(19) United States
(12) Patent Application Publication
(10) Pub. No.: US 2025/0279245 A1
(43) Pub. Date: Sep. 4, 2025

(54) MULTILAYER CERAMIC ELECTRONIC COMPONENT AND MOUNTING STRUCTURE OF MULTILAYER CERAMIC ELECTRONIC COMPONENT

(71) Applicant: Murata Manufacturing Co., Ltd., Nagaokakyo-shi (JP)

(72) Inventors: Tomohiro SASAKI, Nagaokakyo-shi (JP); Masahiro SAKURATANI, Nagaokakyo-shi (JP)

(21) Appl. No.: 19/214,153

(22) Filed: May 21, 2025

Related U.S. Application Data
(63) Continuation of application No. PCT/JP2023/044549, filed on Dec. 13, 2023.

(30) Foreign Application Priority Data
Feb. 24, 2023 (JP) 2023-027342

(51) Int. Cl. H01G 4/30; H01G 4/232

(52) U.S. Cl. CPC H01G 4/30; H01G 4/232

(57) ABSTRACT

A multilayer ceramic electronic component includes a multilayer body including dielectric layers, first and second main surfaces facing away from each other in a lamination direction, first and second side surfaces facing away from each other in a width direction, first and second end surfaces facing away from each other in a length direction, a first inner electrode layer exposed to the first end surface and the second end surface and a second inner electrode layer exposed to the first side surface and the second side surface, first and second outer electrodes connected to the first inner electrode layer, and third and fourth outer electrodes connected to the second inner electrode layer, and a conductor portion electrically connected to the first and second outer electrodes. A DC resistance of the conductor portion is smaller than a DC resistance of the multilayer ceramic capacitor.

### CROSS REFERENCE TO RELATED APPLICATIONS

This application claims the benefit of priority to Japanese Patent Application No. 2023-027342 filed on Feb. 24, 2023 and is a Continuation Application of PCT Application No. PCT/JP2023/044549 filed on Dec. 13, 2023. The entire contents of each application are hereby incorporated herein by reference.

### BACKGROUND OF THE INVENTION

### 1. Field of the Invention

The present invention relates to multilayer ceramic electronic components and mounting structures of the multilayer ceramic electronic components.

### 2. Description of the Related Art

For example, a feed-through three-terminal capacitor is known as a decoupling capacitor used to stabilize the power supply voltage supplied to an integrated circuit component (IC) operating at high speed as well as a noise suppression component for the power supply line supplied to an integrated circuit component (IC). A feed-through three-terminal capacitor generally includes a multilayer body having a first main surface and a second main surface that face away from each other, a first side surface and a second side surface that face away from each other, and a first end surface and a second end surface that face away from each other. Inside the multilayer body, a plurality of first inner electrode layers and a plurality of second inner electrode layers are alternately positioned with each other in a lamination direction. In addition, both ends of each of the first inner electrode layer extend to the first end surface and the second end surface, and both ends of each of the second inner electrode layer extend to the first side surface and the second side surface. Furthermore, the first inner electrode layers are connected to the first outer electrode and the second outer electrode, and the second inner electrode layers are connected to the third outer electrode and the fourth outer electrode.

When a typical feed-through three-terminal capacitor is used as a noise filter, DC current flows through a signal internal electrode (first inner electrode layer). However, in the case of lower capacitance, the number of signal internal electrodes (first inner electrode layers) decreases and the DC resistance increase, and accordingly, a larger amount of heat is generated by the capacitor.

Accordingly, the structure as described in Japanese Unexamined Patent Application Publication No. 9-55335 is provided as the structure of a low-capacitance feed-through three-terminal capacitor that can suppress the DC resistance from increasing while suppressing the electrostatic capacitance from increasing. Both the electrostatic capacitance and the DC resistance are suppressed by increasing the number of signal internal electrodes (first inner electrode layers) and causing the signal internal electrodes (first inner electrode layers) to face each other.

### SUMMARY OF THE INVENTION

However, the structure as described in Japanese Unexamined Patent Application Publication No. 9-55335 has the following problems. That is, there is a limit to the number of signal internal electrodes (first inner electrode layers) that can be increased within a certain size constraint, thereby making measures against larger current difficult. In addition, the inner structure needs to be designed uniquely for each electrostatic capacitance, thereby causing poor scalability of the product lineup.

Accordingly, example embodiments of the present invention provide multilayer ceramic electronic components that each eliminate the need to design the inner structure for each electrostatic capacitance while preventing the electrostatic capacitance and the DC resistance from increasing.

According to an example embodiment of the present invention, a multilayer ceramic electronic component includes a multilayer ceramic capacitor including a multilayer body that includes a plurality of dielectric layers, a first main surface and a second main surface that face away from each other in a lamination direction, a first side surface and a second side surface that face away from each other in a width direction orthogonal to the lamination direction, a first end surface and a second end surface that face away from each other in a length direction orthogonal to both the lamination direction and the width direction, a first inner electrode layer exposed to the first end surface and the second end surface, and a second inner electrode layer exposed to the first side surface and the second side surface, a first outer electrode and a second outer electrode that are connected to the first inner electrode layer, and a third outer electrode and a fourth outer electrode that are connected to the second inner electrode layer, and a conductor portion electrically connected to the first outer electrode and the second outer electrode, wherein a DC resistance RdcA of the conductor portion is smaller than a DC resistance RdcB of the multilayer ceramic capacitor.

According to another example embodiment of the present invention, in a mounting structure of a multilayer ceramic electronic component, the mounting structure includes the multilayer ceramic electronic component according to an example embodiment of the present invention, and a mounting substrate on which the multilayer ceramic electronic component is mounted, in which the multilayer ceramic electronic component is mounted such that the conductor portion does not face the mounting substrate.

In a multilayer ceramic electronic component according to an example embodiment of the present invention, the DC resistance RdcA of the conductor portion connected to the multilayer ceramic capacitor is smaller than the DC resistance RdcB of the multilayer ceramic capacitor. As a result, DC current can be released through the conductor portion to discharge into the multilayer ceramic capacitor. More specifically, since DC current easily flows toward a portion with lower DC resistance, DC current is more likely to flow toward the conductor portion with lower DC resistance than toward the multilayer ceramic capacitor. On the other hand, since AC current easily flows toward a portion with lower impedance, AC current is more likely to flow toward the multilayer ceramic capacitor with lower impedance. The structure as described above can prevent the electrostatic capacitance and the DC resistance of the multilayer ceramic capacitor from increasing. In addition, it is possible to take measures against large current only by attaching a conductor portion to an existing multilayer ceramic capacitor without the need to newly design the inner structure uniquely for each electrostatic capacitance. As a result, the expandability of the product lineup also increases.

In a mounting structure according to an example embodiment of the present invention, a multilayer ceramic electronic component is mounted such that the conductor portion does not face the mounting surface. Since the distance between the multilayer ceramic capacitor and the mounting substrate does not increase in the mounting as described above, the effect of low ESL can be easily obtained. In addition, mounting can be performed without affecting mounting of the multilayer ceramic electronic component 100 on the mounting substrate.

According to example embodiments of the present invention, it is possible to provide multilayer ceramic electronic components and mounting structures of the multilayer ceramic electronic components that eliminate the need to design the inner structure for each electrostatic capacitance while preventing the electrostatic capacitance and the DC resistance from increasing.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view illustrating the appearance of a multilayer ceramic electronic component according to an example embodiment of the present invention.

FIG. 2 is a front view of a multilayer ceramic electronic component according to an example embodiment of the present invention.

FIG. 3 is a perspective view of a multilayer ceramic capacitor according to an example embodiment of the present invention.

FIG. 4 is a front view of the multilayer ceramic capacitor according to an example embodiment of the present invention.

FIG. 5 is a plan view of the multilayer ceramic capacitor according to an example embodiment of the present invention.

FIG. 6 is a cross-sectional view taken along line VI-VI in FIG. 3.

FIG. 7 is a cross-sectional view taken along line VII-VII in FIG. 3.

FIG. 8 is a cross-sectional view taken along line VIII-VIII in FIG. 6.

FIG. 9 is a cross-sectional view taken along line IX-IX in FIG. 6.

FIG. 10 is a cross-sectional view illustrating an example of a conductor portion according to an example embodiment of the present invention.

FIG. 11A is a cross-sectional view illustrating a first modification of a conductor portion according to an example embodiment of the present invention.

FIG. 11B is a cross-sectional view illustrating a second modification of the conductor portion according to an example embodiment of the present invention.

FIG. 11C is a cross-sectional view illustrating a third modification of a conductor portion according to an example embodiment of the present invention.

FIG. 11D is a cross-sectional view illustrating a fourth modification of a conductor portion according to an example embodiment of the present invention.

FIG. 12 is a cross-sectional view taken in a lamination direction illustrating a mounting structure of a multilayer ceramic electronic component according to an example embodiment of the present invention.

FIG. 13 is a cross-sectional view taken in a width direction illustrating a mounting structure of a multilayer ceramic electronic component according to an example embodiment of the present invention.

FIG. 14 is a cross-sectional view taken in the lamination direction illustrating another mounting structure of a multilayer ceramic electronic component according to an example embodiment of the present invention.

FIG. 15 is a cross-sectional view taken in the width direction illustrating the other mounting structure of a multilayer ceramic electronic component according to an example embodiment of the present invention.

FIG. 16 is a cross-sectional view illustrating a first modification of a multilayer ceramic capacitor according to an example embodiment of the present invention and corresponds to the cross-sectional view in FIG. 6.

FIG. 17 is a cross-sectional view illustrating the first modification of a multilayer ceramic capacitor according to an example embodiment of the present invention and corresponds to the cross-sectional view in FIG. 7.

FIG. 18 is a cross-sectional view taken along line XVIII-XVIII in FIG. 16.

FIG. 19 is a cross-sectional view taken along line XIX-XIX in FIG. 16.

FIG. 20 is a cross-sectional view illustrating a second modification of a multilayer ceramic capacitor according to an example embodiment of the present invention and corresponds to the cross-sectional view in FIG. 6.

FIG. 21 is a cross-sectional view illustrating the second modification of a multilayer ceramic capacitor according to an example embodiment of the present invention and corresponds to the cross-sectional view in FIG. 7.

FIG. 22 is a cross-sectional view illustrating a third modification of a multilayer ceramic capacitor according to an example embodiment of the present invention and corresponds to the cross-sectional view in FIG. 6.

FIG. 23 is a cross-sectional view illustrating the third modification of a multilayer ceramic capacitor according to an example embodiment of the present invention and corresponds to the cross-sectional view in FIG. 7.

### DETAILED DESCRIPTION OF THE EXAMPLE EMBODIMENTS

### 1. Multilayer Ceramic Electronic Component

A multilayer ceramic electronic component 100 according to an example embodiment of the present invention will be described.

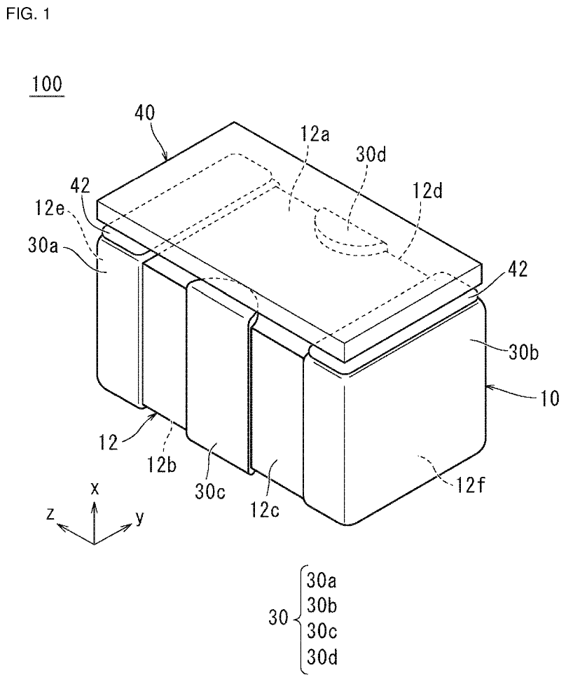

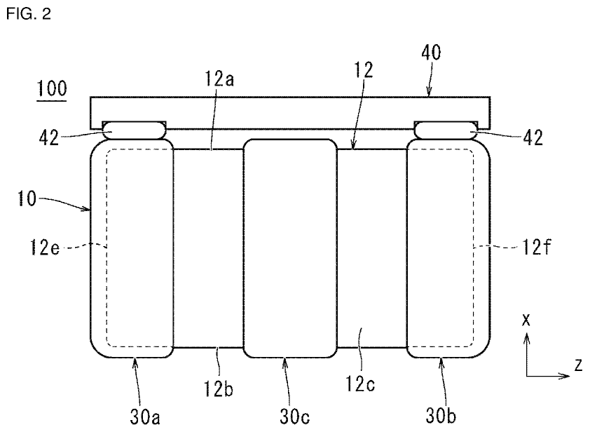

FIG. 1 is a perspective view illustrating the appearance of the multilayer ceramic electronic component according to the present example embodiment of the present invention. FIG. 2 is a front view of the multilayer ceramic electronic component according to the present example embodiment of the present invention.

As illustrated in FIGS. 1 and 2, the multilayer ceramic electronic component 100 according to the present example embodiment of the present invention includes a multilayer ceramic capacitor 10 and a conductor portion 40.

### (a) Multilayer Ceramic Capacitor

The multilayer ceramic capacitor 10 according to the present example embodiment of the present invention will be described.

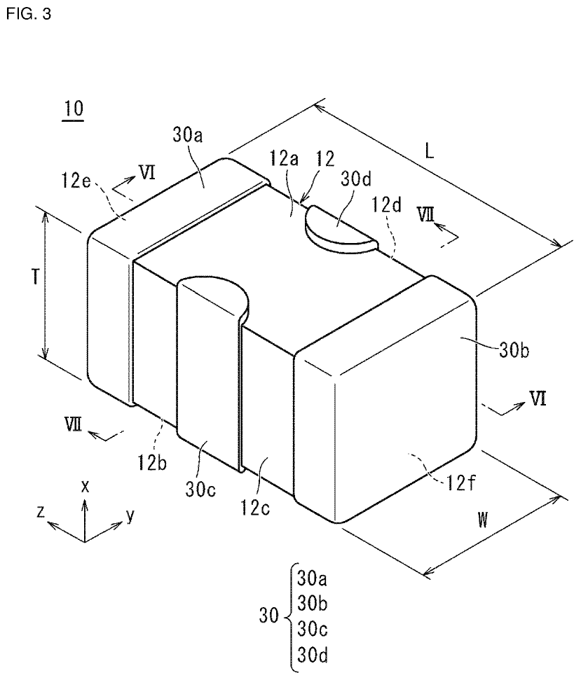

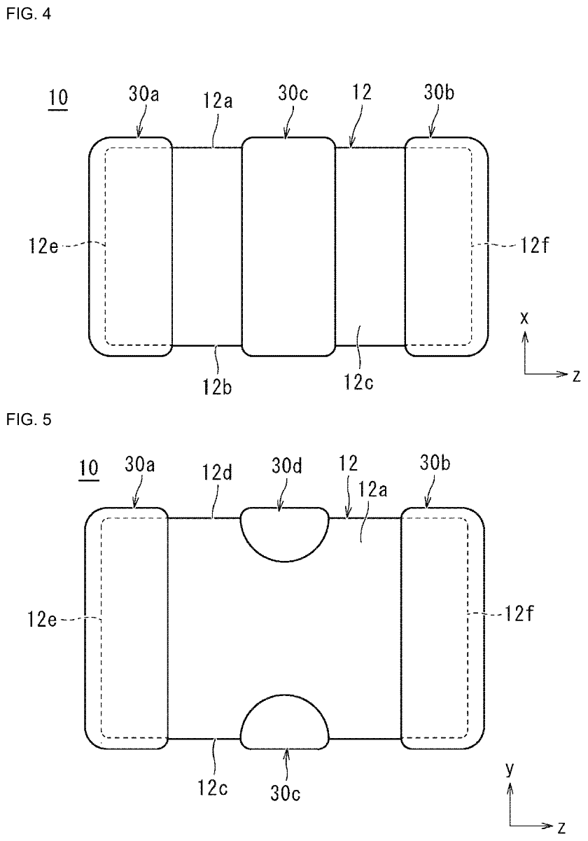

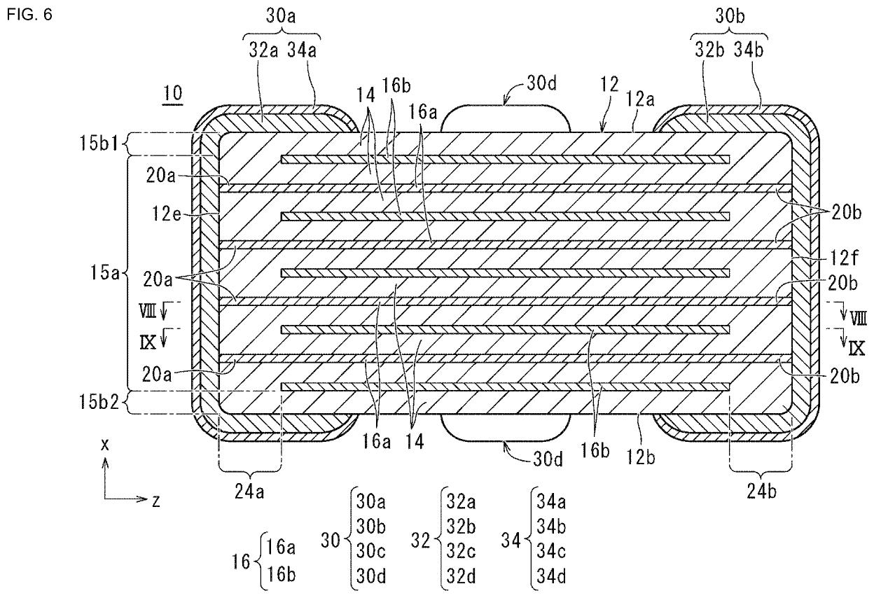

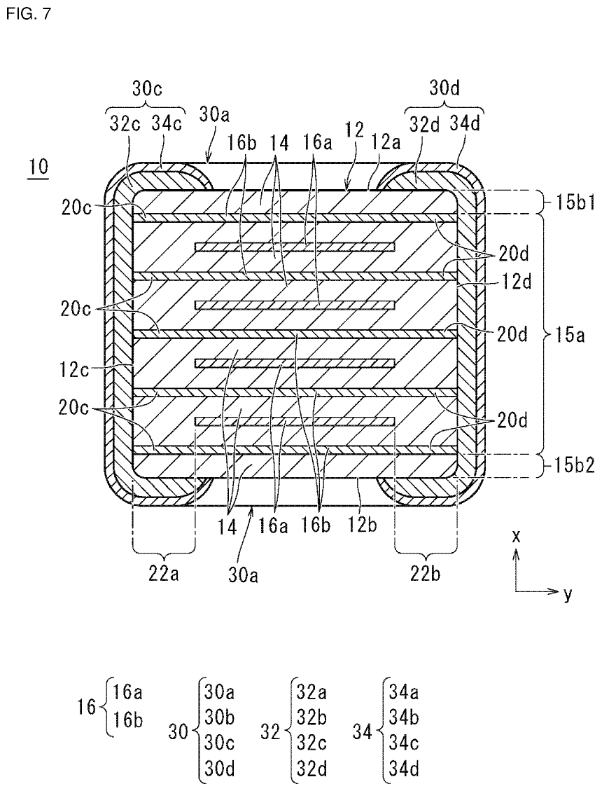

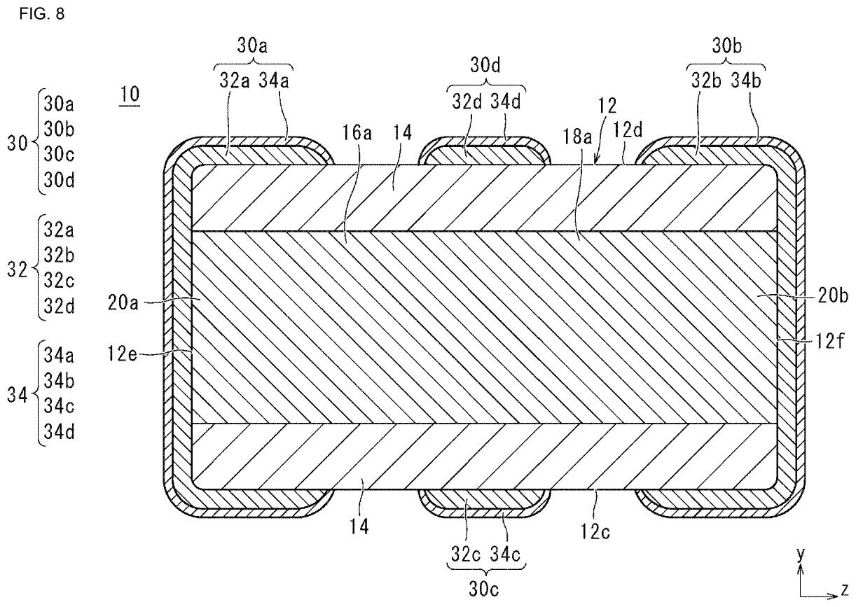

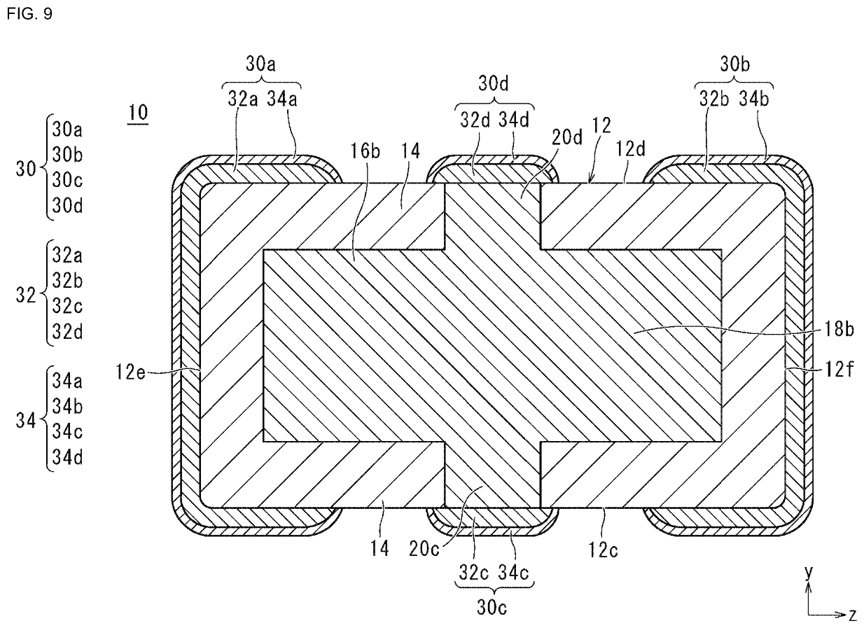

FIG. 3 is a perspective view of the multilayer ceramic capacitor according to the present example embodiment of the present invention. FIG. 4 is a front view of the multilayer ceramic capacitor according to the present example embodiment of the present invention. FIG. 5 is a plan view of the multilayer ceramic capacitor according to the present example embodiment of the present invention. FIG. 6 is a cross-sectional view taken along line VI-VI in FIG. 3. FIG. 7 is a cross-sectional view taken along line VII-VII in FIG. 3. FIG. 8 is a cross-sectional view taken along line VIII-VIII in FIG. 6. FIG. 9 is a cross-sectional view taken along line IX-IX in FIG. 6.

The multilayer ceramic capacitor 10 includes a multilayer body 12 and an outer electrode 30. The structure of the multilayer body 12 and the structure of the outer electrode 30 will be described below in this order.

### Multilayer Body

The multilayer body 12 includes a plurality of dielectric layers 14 having been laminated together. In addition, the multilayer body 12 includes a first main surface 12a and a second main surface 12b that face away from each other in a lamination direction x, a first side surface 12c and a second side surface 12d that face away from each other in a width direction y orthogonal to the lamination direction x, and a first end surface 12e and a second end surface 12f that face away from each other in a length direction z orthogonal to both the lamination direction x and the width direction y. The multilayer body 12 has a rectangular or substantially rectangular shape, for example. In addition, the multilayer body 12 preferably has rounded corner portions and rounded ridge portions. It should be noted that each of the corner portions refers to a portion in which three adjacent surfaces of the multilayer body 12 intersect each other, and each of the ridge portions refers to a portion in which two adjacent surfaces of the multilayer body 12 intersect each other. In addition, some or all of the first main surface 12a and the second main surface 12b, the first side surface 12c and the second side surface 12d, and the first end surface 12e and the second end surface 12f may have bumps and dips.

As illustrated in FIGS. 3 to 9, the multilayer body 12 includes an inner layer portion 15a in which a plurality of inner electrode layers 16 are alternately positioned with each other via dielectric layers 14, a first outer layer portion 15b1, located closer to the first main surface 12a, that includes a plurality of dielectric layers 14 located between the first main surface 12a and the outermost surface of the inner layer portion 15a closer to the first main surface 12a, and a second outer layer portion 15b2, located closer to the second main surface 12b, that includes a plurality of dielectric layers 14 located between the second main surface 12b and the outermost surface of the inner layer portion 15a closer to the second main surface 12b.

Here, the plurality of dielectric layers 14 for inner layers that provide the inner layer portion 15a are sandwiched between first inner electrode layers 16a and second inner electrode layers 16b, which will be described later.

The number of dielectric layers 14 including the first outer layer portion 15b1 and the second outer layer portion 15b2 to be laminated together is not particularly limited but is preferably 10 or more and 1000 or less, for example. In addition, the thickness of the dielectric layer 14 is preferably about 0.5 μm or more and about 15 μm or less, for example.

The dielectric layer 14 can be made of a dielectric material as, for example, a ceramic material. Dielectric ceramic including components, such as BaTiO₃, CaTiO₃, SrTiO₃, or CaZnO₃ can be used as the dielectric material as described above. In addition, when the dielectric materials described above are included as main components, depending on the desired characteristics of the multilayer body 12, additives including accessory components with a lower content than main components, such as Mn compounds, Fe compounds, Cr compounds, Co compounds, or Ni compounds may be used.

In addition, the dielectric layer 14 may include a plurality of crystal grains including a perovskite-type compounds based on BaTiO₃. The size of the crystal grains is appropriately designed in accordance with the thickness of the dielectric layer 14. In the present example embodiment, since the capacitance of the capacitor increases as the thickness of the dielectric layer 14 is thin, the crystal grain diameter is preferably about 1 μm or less, for example.

Furthermore, the dielectric layers 14 for outer layers that provide the first outer layer portion 15b1 and the second outer layer portion 15b2 are made of the same dielectric ceramic material as the dielectric layers 14 of the inner layer portion 15a. It should be noted that the dielectric layers 14 of the first outer layer portion 15b1 and the second outer layer portion 15b2 may be made of materials different from the material of the dielectric layers 14 of the inner layer portion 15a. It should be noted that the dielectric layers 14 of the first outer layer portion 15b1 and the second outer layer portion 15b2 may have a multilayer structure or a single-layer structure. In addition, when the dielectric layers 14 of the first outer layer portion 15b1 and the second outer layer portion 15b2 have a multilayer structure, Si segregation portions in the dielectric layers 14 of the first outer layer portion 15b1 and the second outer layer portion 15b2 that are closest to the first inner electrode layers 16a and the second inner electrode layers 16b are preferably less than segregation portions in the dielectric layers of the first outer layer portions 15b1 and the second outer layer portion 15b2 other than above. As a result, the bending strength in the lamination direction x of the multilayer ceramic capacitor 10 can be improved.

The multilayer body 12 includes side portions (referred to below as W-gaps) 22a and 22b of the multilayer body 12 that are located between the first inner electrode layers 16a and the first side surface 12c and between the first inner electrode layers 16a and the second side surface 12d.

In addition, the multilayer body 12 includes end portions (referred to below as L-gaps) 24a and 24b of the multilayer body 12 that are located between the second inner electrode layers 16b and the first end surface 12e and between the second inner electrode layers 16b and the second end surface 12f.

### Inner Electrode Layer

As illustrated in FIGS. 3 and 9, the inner electrode layer 16 includes the first inner electrode layers 16a exposed to the first end surface 12e and the second end surface 12f and the second inner electrode layers 16b exposed to the first side surface 12c and the second side surface 12d.

The first inner electrode layer 16a includes a first facing electrode portion 18a that faces the second inner electrode layer 16b, a first extended electrode portion 20a, located on one end side of the first inner electrode layer 16a, that extends from the first facing electrode portion 18a to the first end surface 12e of the multilayer body 12, and a second extended electrode portion 20b, located on one end side of the first inner electrode layer 16a, that extends from the first facing electrode portion 18a to the second end surface 12f of the multilayer body 12.

The second inner electrode layer 16b includes a second facing electrode portion 18b that faces the first inner electrode layer 16a, a third extended electrode portion 20c, located on one end side of the second inner electrode layer 16b, that extends from the second facing electrode portion 18b to the first side surface 12c of the multilayer body 12, and a fourth extended electrode portion 20d, located on one end side of the second inner electrode layer 16b, that extends from the second facing electrode portion 18b to the second side surface 12d of the multilayer body 12.

The shape of the first facing electrode portion 18a of the first inner electrode layer 16a is not particularly limited but is preferably rectangular in plan view. However, the corner portions may be rounded in plan view, or the corner portions may be diagonal (tapered) in plan view. In addition, the shape may be tapered toward either end in plan view.

The shape of the second facing electrode portion 18b of the second inner electrode layer 16b is not particularly limited but is preferably rectangular in plan view. However, the corner portions may be rounded in plan view, or the corner portions may be diagonal (tapered) in plan view. In addition, the shape may be tapered toward either end in plan view.

The shapes of the first extended electrode portion 20a and the second extended electrode portion 20b of the first inner electrode layer 16a are not particularly limited but are preferably rectangular in plan view. However, the corner portions may be rounded in plan view, or the corner portions may be diagonal (tapered) in plan view. In addition, the shape may be tapered in plan view toward either end.

The shapes of the third extended electrode portion 20c and the fourth extended electrode portion 20d of the second inner electrode layer 16b are not particularly limited but are preferably rectangular in plan view. However, the corner portions may be rounded in plan view, or the corner portions may be diagonal (tapered) in plan view. In addition, the shape may be tapered in plan view toward either end.

The width of the first facing electrode portion 18a of the first inner electrode layer 16a and the width of the first extended electrode portion 20a and the second extended electrode portion 20b of the first inner electrode layer 16a may be the same with each other, or the width of one of them may smaller than the width of the other.

The width of the second facing electrode portion 18b of the second inner electrode layer 16b and the width of the third extended electrode portion 20c and the fourth extended electrode portion 20d of the second inner electrode layer 16b may be the same with each other, or the width of one of them may be smaller than the width of the other.

In the present example embodiment, the width in the length direction z of the third extended electrode portion 20c and the fourth extended electrode portion 20d of the second inner electrode layer 16b is smaller than the width in the length direction z of the second facing electrode portion 18b of the second inner electrode layer 16b.

In addition, the first inner electrode layer 16a has a uniform thickness, but the thickness of the edge portion of the first inner electrode layer 16a may be greater than the thickness of the central portion. When the thickness of the first inner electrode layer 16a increases, coverage is improved. As a result, the current path is shortened, and the ESL characteristics are improved. Alternatively, the thickness of the edge of the first inner electrode layer 16a may be smaller than the thickness of the central portion. When the thickness decreases, the step height of the thickness of the first inner electrode layer 16a decreases, and structural defects are reduced or prevented.

The material of the first inner electrode layer 16a and the second inner electrode layer 16b may be a conductive material, such as a metal such as Ni, Cu, Ag, Pd, Au, or an alloy including at least one of these metals, such as an Ag—Pd alloy, but the material of the first inner electrode layer 16a is not limited to these.

In the present example embodiment, capacitance is generated because the first facing electrode portion 18a of the first inner electrode layer 16a faces the second facing electrode portion 18b of the second inner electrode layer 16b via the dielectric layer 14, and accordingly, the characteristics of the capacitor are exhibited.

The thicknesses of the first inner electrode layer 16a and the second inner electrode layer 16b are preferably about 0.5 μm or more and about 1.5 μm or less, for example. In addition, the number of the first inner electrode layers 16a and the second inner electrode layers 16b is appropriately changed depending on the size and the like. The DC resistance can be prevented from increasing by increasing the number of the first inner electrode layers 16a. The total number of the first inner electrode layers 16a and the second inner electrode layers 16b is preferably 10 or more and 1000 or less, for example.

The first extended electrode portion 20a and the second extended electrode portion 20b of the first inner electrode layer 16a may be curved. In addition, the third extended electrode portion 20c and the fourth extended electrode portion 20d of the second inner electrode layer 16b may be curved. At this time, the extended electrode portions may be curved toward one of the first main surface 12a and the second main surface 12b. In this case, the current path can be shortened by the mounting surface being curved.

The distance between the first inner electrode layer 16a closest to the first main surface 12a and the first inner electrode layer 16a closest to the second main surface 12b of the first inner electrode layers 16a drawn to the first end surface 12e and the second end surface 12f may be smaller than the distance between the first facing electrode portion 18a of the first inner electrode layer 16a closest to the first main surface 12a and the first facing electrode portion 18a of the first inner electrode layer 16a closest to the second main surface 12b.

In addition, the distance between the second inner electrode layer 16b closest to the first main surface 12a and the second inner electrode layer 16b closest to the second main surface 12b of the second inner electrode layers 16b drawn to the first side surface 12c and the second side surface 12d may be smaller than the distance between the second facing electrode portion 18b of the second inner electrode layer 16b closest to the first main surface 12a and the second facing electrode portion 18b of the second inner electrode layer 16b closest to the second main surface 12b.

It should be noted that, since the area of the inner electrode layers 16 needs to be increased to increase the capacitance of the capacitor, the LW surface coverage of the inner electrode layers 16 is preferably about 90% or more, for example. Here, the LW surface coverage of the inner electrode layers 16 is defined as the ratio obtained by subtracting the area of voids from the area of the edge portions of the inner electrode layers 16, as viewed from the LW surface of the multilayer body 12. The higher the LW surface coverage of the inner electrode layers 16, the greater the capacitance of the capacitor. However, the dielectric layers 14 are joined to each other via voids even when the LW surface coverage low, and accordingly, interlayer joint strength becomes high and interlayer delamination is less likely to occur.

### Outer Electrode

The outer electrode 30 includes a first outer electrode 30a, a second outer electrode 30b, a third outer electrode 30c, and a fourth outer electrode 30d.

The first outer electrode 30a is connected to the first inner electrode layer 16a and is provided on the first end surface 12e. In addition, the first outer electrode 30a is disposed on a portion of the first main surface 12a and a portion of the second main surface 12b. It should be noted that the first outer electrode 30a may wrap around a portion of the first side surface 12c and a portion of the second side surface 12d more or less.

The second outer electrode 30b is connected to the first inner electrode layer 16a and is provided on the second end surface 12f. In addition, the second outer electrode 30b is preferably disposed on a portion of the first main surface 12a and a portion of the second main surface 12b. It should be noted that the second outer electrode 30b may wrap around a portion of the first side surface 12c and a portion of the second side surface 12d more or less.

The third outer electrode 30c is connected to the second inner electrode layer 16b and is provided on the first side surface 12c. In addition, the third outer electrode 30c is preferably disposed on a portion of the first main surface 12a and a portion of the second main surface 12b. In addition, the third outer electrode 30c may be disposed on either a portion of the first main surface 12a or a portion of the second main surface 12b continuously from the first side surface 12c.

The fourth outer electrode 30d is connected to the second inner electrode layer 16b and is provided on the second side surface 12d. In addition, the fourth outer electrode 30d is preferably disposed on a portion of the first main surface 12a and a portion of the second main surface 12b. In addition, the fourth outer electrode 30d may be disposed on either a portion of the first main surface 12a or a portion of the second main surface 12b continuously from the second side surface 12d.

The third outer electrode 30c and the fourth outer electrode 30d may be directly joined to each other.

The first outer electrode 30a includes a first underlying electrode layer 32a including a conductive metal disposed on the multilayer body 12 and includes a first plating layer 34a disposed so as to cover the first underlying electrode layer 32a.

The second outer electrode 30b includes a second underlying electrode layer 32b including the conductive metal disposed on the multilayer body 12 and includes a second plating layer 34b disposed so as to cover the second underlying electrode layer 32b.

The third outer electrode 30c includes a third underlying electrode layer 32c including the conductive metal disposed on the multilayer body 12 and includes a third plating layer 34c disposed so as to cover the third underlying electrode layer 32c.

The fourth outer electrode 30d includes a fourth underlying electrode layer 32d including the conductive metal disposed on the multilayer body 12 and includes a fourth plating layer 34d disposed so as to cover the fourth underlying electrode layer 32d.

An underlying electrode layer 32 includes the first underlying electrode layer 32a, the second underlying electrode layer 32b, the third underlying electrode layer 32c, and the fourth underlying electrode layer 32d. Each of the first underlying electrode layer 32a, the second underlying electrode layer 32b, the third underlying electrode layer 32c, and the fourth underlying electrode layer 32d includes at least one selected from the group consisting of a baking layer, a conductive resin layer, a thin film layer, and the like.

The baking layer includes a glass component and a metal. The baking layer may include a plurality of layers.

The glass component of the baking layer includes at least one selected from the group consisting of B, Si, Ba, Mg, Al, or Li, and the like.

The metal of the baking layer includes at least one of, for example, Cu, Ni, Ag, Pd, an Ag—Pd alloy, or Au.

The baking layer is formed by applying a conductive paste including glass and metal to the multilayer body 12 and burning the applied conductive paste, and the baking layer may be burnt at the same time with the inner electrode layer 16 or may be burned after the inner electrode layer 16 is burnt.

When the baking layers are provided as the first underlying electrode layer 32a and the second underlying electrode layer 32b, the thicknesses of the baking layers in the central portion in the lamination direction x of the first underlying electrode layer 32a and the second underlying electrode layer 32b located on the first end surface 12e and the second end surface 12f are preferably, for example, about 20 μm or more and about 50 μm or less.

In addition, when the baking layers are provided as the first underlying electrode layer 32a and the second underlying electrode layer 32b on the first main surface 12a, the second main surface 12b, the first side surface 12c, and the second side surface 12d, the thicknesses of the baking layers in the central portion in the length direction z of the first underlying electrode layer 32a and the second underlying electrode layer 32b located on the first main surface 12a, the second main surface 12b, the first side surface 12c, and the second side surface 12d are preferably, for example, about 5 μm or more and about 20 μm or less.

When the baking layers are provided as the third underlying electrode layer 32c and the fourth underlying electrode layer 32d, the thicknesses of the baking layers in the central portion in the lamination direction x of the third underlying electrode layer 32c and the fourth underlying electrode layer 32d located on the first side surface 12c and the second side surface 12d are preferably, for example, about 20 μm or more and about 50 μm or less.

In addition, when the baking layers are provided as the third underlying electrode layer 32c and the fourth underlying electrode layer 32d on the first main surface 12a and the second main surface 12b, the thicknesses of the baking layers in the central portion in the length direction z of the third underlying electrode layer 32c and the fourth underlying electrode layer 32d located on the first main surface 12a and the second main surface 12b are preferably, for example, about 5 μm or more and about 20 μm or less.

Next, a case in which the underlying electrode layer 32 is formed as the conductive resin layer will be described. The conductive resin layer may be disposed on the baking layer to cover the baking layer or may be disposed directly on the multilayer body 12 without the baking layer being provided. In addition, the conductive resin layer may completely cover the baking layer or may cover a portion of the baking layer. Furthermore, the conductive resin layer may include a plurality of layers.

The conductive resin layer includes a thermosetting resin and a metal. Since the conductive resin layer includes a thermosetting resin, the conductive resin layer is more flexible than the baking layer that includes, for example, a plating film or a burned product of a conductive paste. Accordingly, even when a physical shock or a shock caused by thermal cycles is applied to the multilayer ceramic capacitor 10, the conductive resin layer functions as a buffer layer to prevent cracks from developing in the multilayer ceramic capacitor 10.

The conductive resin layer may include metals of Ag, Cu, Ni, Sn, or Bi or alloys including these metals. In addition, Ag-coated metal powder can also be used. When Ag-coated metal powder is used, the metal powder is preferably made of Cu, Ni, Sn, or Bi, or an alloy including one of these metals. The reason why Ag conductive metal powder is used as the conductive metals is that Ag has the lowest resistivity among all metals and is suitable for an electrode material, and that Ag does not oxidize and has high weather resistance because Ag is a precious metal. In addition, the reason why an Ag-coated metal is used is that the base metal can be inexpensive while the characteristics of Ag described above is kept.

The metal included in the conductive resin layer is primarily contributes to the electrical conductivity of the conductive resin layer. Specifically, contact between metals (conductive fillers) included in the conductive resin layer provides an electrical conduction path within the conductive resin layer.

The metals included in the conductive resin layer may be spherical or flat, but a mixture of spherical metal powder and flat metal powder is preferable. The average particle diameter of the metals included in the conductive resin layer is not particularly limited. The average particle diameter of the metals (conductive fillers) included in the conductive resin layer may be, for example, about 0.3 μm or more and about 10 μm or less.

The volume percent of the metals included in the conductive resin layer relative to the total volume of the conductive resin is preferably about 35 vol % or more and about 75 vol % or less, for example.

Various known thermosetting resins, such as epoxy resin, phenolic resin, urethane resin, silicone resin, or polyimide resin, can be used as the resin for the conductive resin layer. Among them, epoxy resin, which excels in heat resistance, moisture resistance, and close contact, is one of the most suitable resins.

The volume percent of the resin included in the conductive resin layer relative to the total volume of the conductive resin is preferably about 25 vol % or more and about 65 vol % or less, for example.

In addition, the conductive resin layer preferably includes a hardening agent together with the thermosetting resin. When epoxy resin is used as the base resin, various known compounds, such as phenolic, amine, anhydride, imidazole, reactive ester, and amide-imide compounds, can be used as the hardening agents for the epoxy resin.

When conductive resin electrode layers are provided as the first underlying electrode layer 32a and the second underlying electrode layer 32b, the thickness of the conductive resin electrode layers in the central portion in the lamination direction x of the first underlying electrode layer 32a and the second underlying electrode layer 32b located on the first end surface 12e and the second end surface 12f is preferably, for example, about 20 μm or more and about 70 μm or less.

In addition, when conductive resin electrode layers are provided as the first underlying electrode layer 32a and the second underlying electrode layer 32b on the first main surface 12a, the second main surface 12b, the first side surface 12c, and the second side surface 12d, the thicknesses of the conductive resin electrode layers in the central portion in the length direction z of the first underlying electrode layer 32a and the second underlying electrode layer 32b located on the first main surface 12a, the second main surface 12b, the first side surface 12c, and the second side surface 12d are preferably, for example, about 5 μm or more and about 20 μm or less.

When conductive resin electrode layers are provided as the third underlying electrode layer 32c and the fourth underlying electrode layer 32d, the thicknesses of the conductive resin electrode layers in the central portion in the lamination direction x of the third underlying electrode layer 32c and the fourth underlying electrode layer 32d located on the first side surface 12c and the second side surface 12d are preferably, for example, about 20 μm or more and about 70 μm or less.

In addition, when conductive resin electrode layers are provided as the third underlying electrode layer 32c and the fourth underlying electrode layer 32d on the first main surface 12a and the second main surface 12b, the thicknesses of the conductive resin electrode layers in the central portion in the length direction z of the third underlying electrode layer 32c and the fourth underlying electrode layer 32d located on the first main surface 12a and the second main surface 12b are preferably, for example, about 5 μm or more and about 20 μm or less.

It should be noted that only the conductive resin electrode layers may also be disposed as the first underlying electrode layer 32a and the second underlying electrode layer 32b, and only the conductive resin electrode layers may also be disposed as the third underlying electrode layer 32c and the fourth underlying electrode layer 32d.

### Plating Layer

The plating layer 34 includes a first plating layer 34a, a second plating layer 34b, a third plating layer 34c, and a fourth plating layer 34d.

The first plating layer 34a is disposed so as to cover the first underlying electrode layer 32a. The second plating layer 34b is disposed so as to cover the second underlying electrode layer 32b. The third plating layer 34c is disposed so as to cover the third underlying electrode layer 32c. The fourth plating layer 34d is disposed so as to cover the fourth underlying electrode layer 32d.

The plating layer 34 includes at least one of, for example, Cu, Ni, Sn, Ag, Pd, an Ag—Pd alloy, or Au.

In addition, the plating layer 34 may include a plurality of layers. The plating layer 34 preferably has a two-layer structure including Ni plating and Sn plating in this order. The Ni plating layer can prevent the underlying electrode layer 32 from being eroded by solder used to mount the multilayer ceramic capacitor 10. In addition, the Sn plating layer improves the wettability of the solder used to mount the multilayer ceramic capacitor 10, and accordingly, the multilayer ceramic capacitor 10 can be easily mounted. When the plating layer 34 has a three-layer structure, the plating layer 34 preferably includes Sn plating, Ni plating, and Sn plating as viewed from the multilayer body 12.

In addition, the thickness of each of the layers included in the plating layer 34 is preferably about 1 μm or more and about 6 μm or less.

One or each of the first outer electrode 30a, the second outer electrode 30b, the third outer electrode 30c, and the fourth outer electrode 30d may have a direct plating layer formed on the surface of the multilayer body 12. That is, the multilayer ceramic capacitor 10 may have a structure that includes a plating layer directly electrically connected to the first inner electrode layer 16a and the second inner electrode layer 16b. In such a case, after a catalyst is provided on the surface of the multilayer body 12 as a pre-treatment, a direct plating layer may be formed.

The first direct plating layer is formed to be disposed on the first end surface 12e and be joined to the first inner electrode layer 16a. The second direct plating layer is formed to be disposed on the second end surface 12f and be joined to the first inner electrode layer 16a. The third direct plating layer is formed to be disposed on the first side surface 12c and be joined to the second inner electrode layer 16b. The fourth direct plating layer is formed to be disposed on the second side surface 12d and be joined to the second inner electrode layer 16b.

Each of the direct plating layers preferably includes at least one of, for example, Cu, Ni, Sn, Pb, Au, Ag, Pd, Bi, or Zn or an alloy including this metal.

For example, when the first inner electrode layer 16a and the second inner electrode layer 16b are formed to include Ni, the direct plating layer is preferably formed to include Cu, which has good adhesion to Ni.

When the plating layer 34 is formed directly on the multilayer body 12, the thickness of each layer of the plating layer 34 is preferably about 1 μm or more and about 15 μm or less.

When the plating layer 34 is formed directly on the multilayer body 12, the plating layer 34 preferably does not contain glass. In addition, the metal ratio per unit volume of the plating layer 34 is preferably about 99 vol % or more, for example.

A case in which the underlying electrode layer 32 is formed as a thin film layer and the plating layer 34 is formed directly on the thin film layer will be described.

The first thin film layer disposed on the first main surface 12a is connected to the first direct plating layer that wraps around from the first end surface 12e. The second thin film layer disposed on the first main surface 12a is connected to the second direct plating layer that wraps around from the second end surface 12f. The third thin film layer disposed on the first main surface 12a is connected to the third direct plating layer that wraps around from the first side surface 12c. The fourth thin film layer disposed on the first main surface 12a is connected to the fourth direct plating layer that wraps around from the second side surface 12d.

Similarly, the first thin film layer disposed on the second main surface 12b is connected to the first direct plating layer that wraps around from the first end surface 12e. The second thin film layer disposed on the second main surface 12b is connected to the second direct plating layer that wraps around from the second end surface 12f. The third thin film layer disposed on the second main surface 12b is connected to the third direct plating layer that wraps around from the first side surface 12c. The fourth thin film layer disposed on the second main surface 12b is connected to the fourth direct plating layer that wraps around from the second side surface 12d.

The dimension in the length direction z of the multilayer ceramic capacitor 10 including the multilayer body 12 and the outer electrode 30 is assumed to be dimension L. Dimension L is preferably about 1.0 mm or more and about 3.2 mm or less, for example.

The dimension in the lamination direction x of the multilayer ceramic capacitor 10 including the multilayer body 12 and the outer electrode 30 is assumed to be dimension T. Dimension T is preferably about 0.3 mm or more and about 2.5 mm or less, for example.

The dimension in the width direction y of the multilayer ceramic capacitor 10 including the multilayer body 12 and the outer electrode 30 is assumed to be dimension W. Dimension W is preferably about 0.5 mm or more and about 2.5 mm or less, for example.

### (b) Conductor Portion

Next, the conductor portion 40 will be described. The conductor portion 40 is electrically connected to the first outer electrode 30a and the second outer electrode 30b of the multilayer ceramic capacitor 10 via a conductive adhesive conductor portion 42.

The conductor portion 40 is formed as, for example, an interposer substrate.

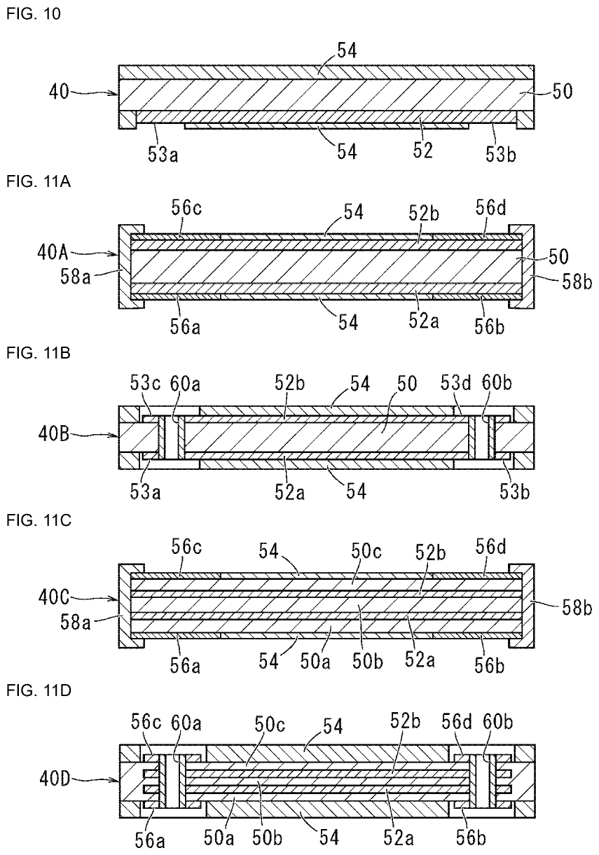

FIG. 10 is a cross-sectional view illustrating an example of the conductor portion. The conductor portion 40 formed as a single-sided substrate. Specifically, the conductor portion 40 includes an insulating substrate 50 and a conductive pattern 52 disposed on one main surface of the insulating substrate 50.

A protective layer 54 is disposed on the surface of the conductive pattern 52 such that portions of the conductive pattern 52 are exposed. The exposed portions of the conductive pattern 52 are a pair of exposed electrode portions 53a and 53b. In addition, a protective layer 54 is disposed on the entire surface of the other main surface of the insulating substrate 50. It should be noted that the protective layer 54 does not need to be formed on the other main surface of the insulating substrate 50.

One of the exposed electrode portions 53a is electrically connected to the first outer electrode 30a via the conductive adhesive conductor portion 42. The other of the exposed electrode portions 53b is electrically connected to the second outer electrode 30b via the conductive adhesive conductor portion 42.

It should be noted that the conductor portion 40 may be rectangular or discoid, and the shape thereof is not limited. However, when the conductor portion 40 is disposed on the first main surface 12a or the second main surface 12b, an increase in the thickness in the lamination direction x of the conductor portion 40 increases the dimension in the lamination direction x of the multilayer ceramic electronic component 100. Accordingly, when the conductor portion 40 is disposed on the first main surface 12a or the second main surface 12b of the multilayer ceramic electronic component 100, the thickness of the conductor portion 40 is preferably reduced.

### (c) Modifications of Conductor Portion

The conductor portion 40 is formed as a single-sided substrate that is an interposer substrate but may also be formed as a double-sided substrate or a multilayer substrate. Modifications of the conductor portion 40 will be described below.

A conductor portion 40A, which is a first modification of the conductor portion 40, will be described.

FIG. 11A is a cross-sectional view illustrating the first modification of the conductor portion. The conductor portion 40A is formed as a double-sided substrate. Specifically, the conductor portion 40A includes the insulating substrate 50, a conductive pattern 52a disposed on one main surface of the insulating substrate 50, and a conductive pattern 52b disposed on the other main surface of the insulating substrate 50.

A land electrode portion 56a is disposed on the surface of the conductive pattern 52a closer to one end of the insulating substrate 50, and a land electrode portion 56b is disposed on the surface of the conductive pattern 52a closer to the other end of the insulating substrate 50. On one main surface of the insulating substrate 50, the protective layer 54 is disposed in a portion of the conductive pattern 52a in which the land electrode portions 56a and 56b are not disposed. A land electrode portion 56c is disposed on the surface of the conductive pattern 52b closer to one end of the insulating substrate 50, and a land electrode portion 56d is disposed on the surface of the conductive pattern 52b closer to the other end of the insulating substrate 50.

The protective layer 54 is disposed in a portion of the conductive pattern 52b in which the land electrode portions 56c and 56d are not disposed on the other main surface of the insulating substrate 50.

An interlayer connection conductor (end surface through-hole) 58a through which the land electrode portion 56a and the land electrode portion 56c are electrically connected to each other is disposed at one end of the insulating substrate 50. An interlayer connection conductor (end surface through-hole) 58b through which the land electrode portion 56b and the land electrode portion 56d are electrically connected to each other is disposed at the other end of the insulating substrate 50.

The land electrode portion 56a is electrically connected to the first outer electrode 30a via the conductive adhesive conductor portion 42. The land electrode portion 56b is electrically connected to the second outer electrode 30b via the conductive adhesive conductor portion 42.

Next, a conductor portion 40B, which is the second modification of the conductor portion 40, will be described.

FIG. 11B is a cross-sectional view illustrating the second modification of the conductor portion. The conductor portion 40B is made from a double-sided substrate. Specifically, the conductor portion 40B includes the insulating substrate 50, the conductive pattern 52a disposed on one main surface of the insulating substrate 50, and the conductive pattern 52b disposed on the other main surface of the insulating substrate 50.

The protective layer 54 is disposed on the surface of the conductive pattern 52a to expose portions of the conductive pattern 52a. The exposed portions of the conductive pattern 52a are a pair of exposed electrode portions 53a and 53b. The protective layer 54 is disposed on the surface of the conductive pattern 52b to expose portions of the conductive pattern 52b. The exposed portions of the conductive pattern 52b are a pair of exposed electrode portions 53c and 53d. An interlayer connection conductor (penetrating through-hole) 60a formed to pass through the insulating substrate 50 from one main surface to the other main surface is disposed to provide electrical connectivity between the exposed electrode portions 53a and 53c. An interlayer connection conductor (penetrating through-hole) 60b formed to pass through the insulating substrate 50 from one main surface to the other main surface is disposed to provide electrical connectivity between the exposed electrode portions 53b and 53d.

The exposed electrode portion 53a is electrically connected to the first outer electrode 30a via the conductive adhesive conductor portion 42. The exposed electrode portion 53b is electrically connected to the second outer electrode 30b via the conductive adhesive conductor portion 42.

Next, a conductor portion 40C, which is a third modification of the conductor portion 40, will be described.

FIG. 11C is a cross-sectional view illustrating the third modification of the conductor portion. The conductor portion 40C is formed as a multilayer substrate. Specifically, the conductor portion 40C includes the plurality of insulating substrates 50a to 50c and the conductive patterns 52a and 52b that are alternately positioned with each other via the insulating substrates 50a to 50c. The conductive patterns 52a and 52b are disposed to be exposed from both end surfaces of the insulating substrates 50a to 50c.

The land electrode portion 56a is disposed on the surface closer to one end of the insulating substrate 50a located on one main surface of the conductor portion 40C, and the land electrode portion 56b is disposed on the surface closer to the other end of the insulating substrate 50c located on the other main surface of the conductor portion 40C. The protective layer 54 is disposed in a portion on the surface of the insulating substrate 50a in which the land electrode portions 56a and 56b are not disposed.

The land electrode portion 56c is disposed on the surface closer to one end of the insulating substrate 50c located on the other main surface of the conductor portion 40C, and the land electrode portion 56d is disposed on the surface closer to the other end of the insulating substrate 50c located on the other main surface of the conductor portion 40C. The protective layer 54 is disposed in a portion on the surface of the insulating substrate 50c in which the land electrode portions 56c and 56d are not disposed.

The interlayer connection conductor (end surface through-hole) 58a through which the land electrode portion 56a and the land electrode portion 56c are electrically connected to each other is disposed at one end of the insulating substrates 50a to 50c. At this time, the interlayer connection conductor 58a is also electrically connected to the conductive patterns 52a and 52b. The interlayer connection conductor (end surface through-hole) 58b through which the land electrode portion 56b and the land electrode portion 56d are electrically connected to each other is disposed at the other end of the insulating substrates 50a to 50c. At this time, the interlayer connection conductor 58b is also electrically connected to the conductive patterns 52a and 52b.

The land electrode portion 56a is electrically connected to the first outer electrode 30a via the conductive adhesive conductor portion 42. The land electrode portion 56b is electrically connected to the second outer electrode 30b via the conductive adhesive conductor portion 42.

Next, a conductor portion 40D, which is a fourth modification of the conductor portion 40, will be described.

FIG. 11D is a cross-sectional view illustrating the fourth modification of the conductor portion. The conductor portion 40D is formed as a multilayer substrate. Specifically, the conductor portion 40D includes the plurality of insulating substrates 50a to 50c and the conductive patterns 52a and 52b that are alternately positioned with the insulating substrates 50a to 50c via the insulating substrates 50a to 50c.

The protective layer 54 is disposed on the surface of the insulating substrate 50a located on one main surface side of the conductor portion 40C to expose portions of the insulating substrate 50a. The pair of land electrode portions 56a and 56b are disposed on the exposed portions of the insulating substrate 50a. The protective layer 54 is disposed on the surface of the insulating substrate 50c located on the other main surface side of the conductor portion 40C to expose portions of the insulating substrate 50c. The pair of land electrode portions 56c and 56d are disposed on the exposed portions of the insulating substrate 50c.

The interlayer connection conductor (penetrating through-hole) 60a is formed to pass from the surface of the insulating substrate 50a to the surface of the insulating substrate 50c is disposed to provide electrical conductivity between the land electrode portion 56a and the land electrode portion 56c. At this time, the interlayer connection conductor 60a is also electrically connected to the conductive patterns 52a and 52b. The interlayer connection conductor (penetrating through-hole) formed to pass from the surface of the insulating substrate 50a to the surface of the insulating substrate 50c is disposed to provide electrical conductivity between the land electrode portion 56b and the land electrode portion 56d. At this time, the interlayer connection conductor 60b is also electrically connected to the conductive patterns 52a and 52b.

The land electrode portion 56a is electrically connected to the first outer electrode 30a via the conductive adhesive conductor portion 42. The land electrode portion 56b is electrically connected to the second outer electrode 30b via the conductive adhesive conductor portion 42.

The insulating substrates 50 and 50a to 50c are formed as substrates made of a material in which a base material including a mixture of glass cloth (fabric) and glass non-woven fabric is impregnated with epoxy resin or polyimide resin or as ceramic substrates manufactured by baking sheets made of a mixture of ceramic and glass. It should be noted that the insulating substrates 50 and 50a to 50c may be formed as single-layer substrates or as substrates in which a plurality of layers are laminated together. The thicknesses of the insulating substrates 50 and 50a to 50c are not particularly limited but preferably about 200 μm or more and about 800 μm or less, for example.

It should be noted that the materials of the conductive patterns 52, 52a, and 52b are not particularly limited, and metals, such as Cu, Au, Pd, or Pt, can be used, for example. In addition, the thickness of the conductive patterns 52, 52a, and 52b, that is, the dimension in the lamination direction x, is not particularly limited but preferably about 20 μm or more and about 200 μm or less, for example.

Furthermore, the protective layer 54 is, for example, an etching resist or a solder resist. The material of the protective layer 54 is not particularly limited.

The conductive adhesive conductor portion 42 of the conductor portion 40 may be made of, for example, a high heat-resistant epoxy adhesive agent or solder.

As described above, the conductive adhesive conductor portion 42 is disposed to be electrically connected to the first outer electrode 30a and the second outer electrode 30b of the multilayer ceramic capacitor 10. In other words, the conductor portion 40 is electrically connected to the first outer electrode 30a and the second outer electrode 30b of the multilayer ceramic capacitor 10 via the conductive adhesive conductor portion 42. As described above, by the conductor portion 40 being disposed so as to electrically connected to the first outer electrode 30a and the second outer electrode 30b of the multilayer ceramic capacitor 10, DC current flows through the conductor portion 40, the current flowing through the multilayer ceramic capacitor 10 is reduced, and temperature rise is suppressed.

The DC resistance RdcA of the conductor portion 40 is smaller than the DC resistance RdcB of the multilayer ceramic capacitor 10. That is, RdcA<RdcB is satisfied.

Since the DC resistance RdcA of the conductor portion 40 is smaller than the DC resistance RdcB of the multilayer ceramic capacitor 10, DC current flows through the conductor portion 40 more preferentially, the current flowing through the multilayer ceramic capacitor 10 is reduced, and temperature rise is prevented.

On the other hand, when the DC resistance RdcA of the conductor portion 40 is greater than the DC resistance RdcB of the multilayer ceramic capacitor 10, since the current flowing through the multilayer ceramic capacitor 10 is greater than the current flowing through the conductor portion 40, the effect of measures against large current cannot be easily obtained.

In addition, the conductor portion 40 is not electrically connected to the third outer electrode 30c and the fourth outer electrode 30d. By the conductor portion 40 being electrically connected to only the first outer electrode 30a and the second outer electrode 30b of the multilayer ceramic capacitor 10, DC current flows through the conductor portion 40, the current flowing into the multilayer ceramic capacitor 10 is reduced, and temperature rise is prevented.

It should be noted that the DC resistance values of the conductor portion 40 and the multilayer ceramic capacitor 10 are measured and compared after the conductive adhesive conductor portion 42 that joins the conductor portion 40 and the multilayer ceramic capacitor 10 is detached and removed. It should be noted that the DC resistance values of the conductor portion 40 and the multilayer ceramic capacitor 10 are measured by using the four-terminal method with a current of 100 mA in accordance with JISC2139.

### 2. Mounting Structure of Multilayer Ceramic Electronic Component

Next, a mounting structure 500 of the multilayer ceramic electronic component 100 according to the present example embodiment of the present invention will be described.

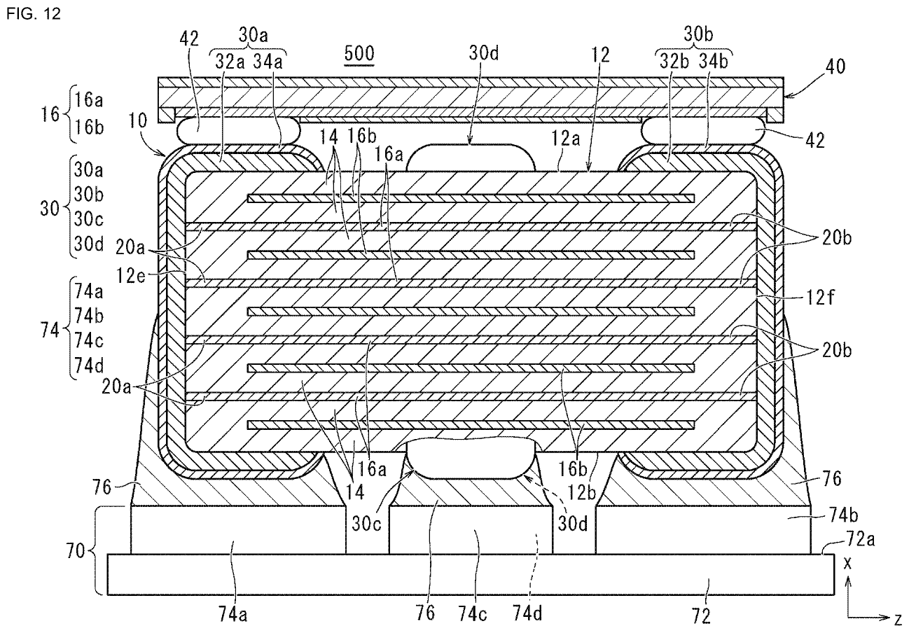

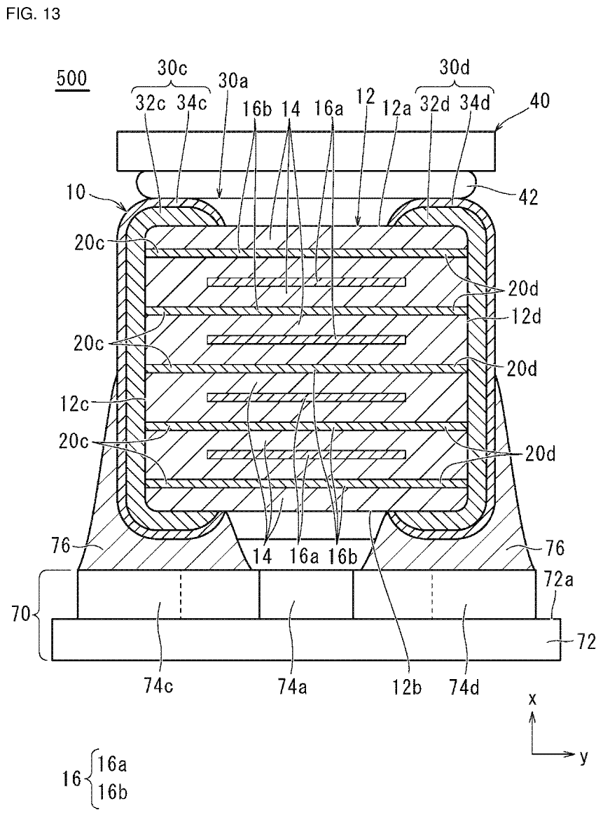

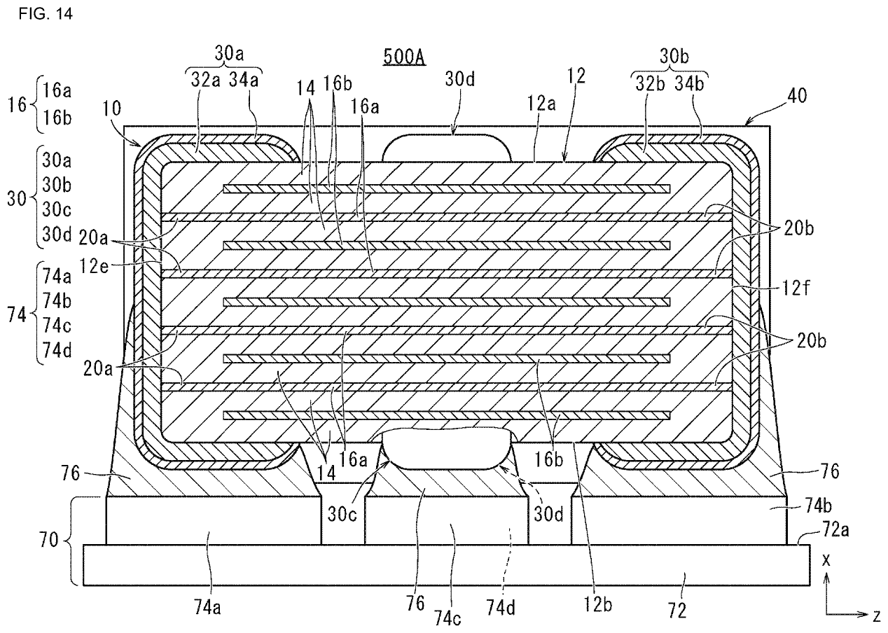

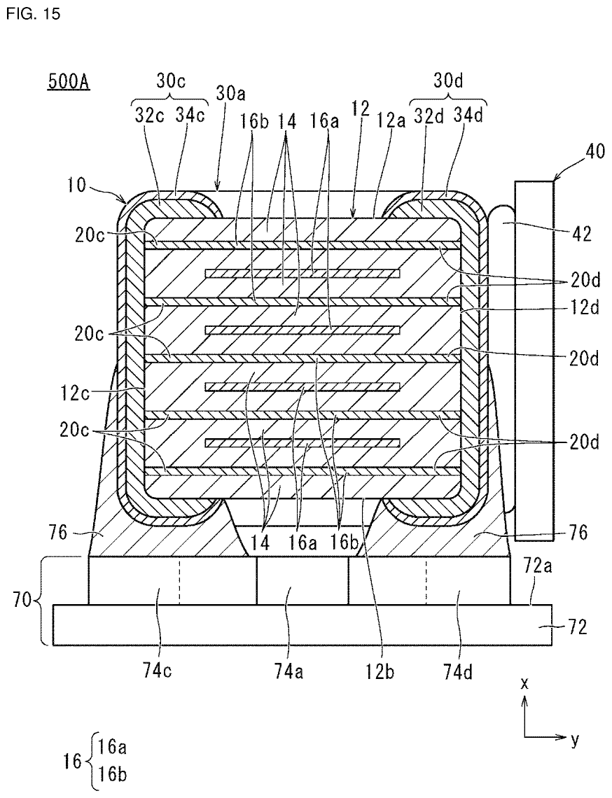

FIG. 12 is a cross-sectional view taken in the lamination direction illustrating the mounting structure of the multilayer ceramic electronic component according to the present example embodiment of the present invention. FIG. 13 is a cross-sectional view taken in the width direction illustrating the mounting structure of the multilayer ceramic electronic component according to the present example embodiment of the present invention. FIG. 14 is a cross-sectional view taken in the lamination direction illustrating another mounting structure of the multilayer ceramic electronic component according to the present example embodiment of the present invention. FIG. 15 is a cross-sectional view taken in the width direction illustrating the other mounting structure of the multilayer ceramic electronic component according to the present example embodiment of the present invention.

As illustrated in FIGS. 12 and 13, the mounting structure 500 of the multilayer ceramic electronic component according to the present example embodiment includes the multilayer ceramic electronic component 100 and the mounting substrate 70 according to the present example embodiment. The mounting substrate 70 includes a core material 72 of the substrate and a connection conductor (conductor land) 74.

The core material 72 of the substrate is formed as a substrate made of a material in which a base material including a mixture of glass cloth (fabric) and glass non-woven fabric is impregnated with epoxy resin or polyimide resin or as a ceramic substrate manufactured by baking a sheet made of a mixture of ceramic and glass. It should be noted that the core material 72 of the substrate may be formed as a single-layer substrate or a substrate in which a plurality of layers are laminated together. The thickness of the core material 72 of the substrate is not particularly limited but is preferably about 200 μm or more and about 800 μm or less.

One main surface of the core material 72 of the substrate forms a substrate-side mounting surface 72a on which the conductor land 74 is disposed and that serves as the mounting surface for the multilayer ceramic electronic component 100.

The conductor land 74 includes a first conductor land 74a, a second conductor land 74b, a third conductor land 74c, and a fourth conductor land 74d.

The first conductor land 74a is a portion that is electrically connected and mechanically joined to the first outer electrode 30a of the multilayer ceramic capacitor 10 via a joining material 76. The second conductor land 74b is a portion that is electrically connected and mechanically joined to the second outer electrode 30b of the multilayer ceramic capacitor 10 via the joining material 76. The third conductor land 74c is a portion that is electrically connected and mechanically joined to the third outer electrode 30c of the multilayer ceramic capacitor 10 via the joining material 76. The fourth conductor land 74d is a portion that is electrically connected and mechanically joined to the fourth outer electrode 30d of the multilayer ceramic capacitor 10 via the joining material 76.

It should be noted that the conductor land 74 may be provided on the main surface opposite to the substrate-side mounting surface 72a of the core material 72.

The material of the conductor land 74 is not particularly limited, and metals such as Cu, Au, Pd, and Pt can be used, for example. In addition, the thickness of the conductor land 74, that is, the dimension in the lamination direction x, is not particularly limited but is preferably about 20 μm or more and about 200 μm or less. The joining material 76 may be made of, for example, a high heat-resistant epoxy adhesive agent or solder.

It should be noted that, in the above description, the mounting substrate 70 corresponds to the mounting substrate according to the present invention. The core material 72 of the substrate corresponds to the core material of the substrate. The substrate-side mounting surface 72a corresponds to the mounting surface. The plurality of conductor lands 74 correspond to the plurality of connection conductors. However, the connection conductor may be a so-called land and is not limited by other applications, functions, shapes, names, and the like as long as the connection conductor is any conductor provided between the multilayer ceramic capacitor 10 and the mounting substrate 70 to electrically connect them.

In the mounting structure 500 of the multilayer ceramic electronic component illustrated in FIGS. 12 and 13, the multilayer ceramic electronic component 100 is preferably mounted such that the conductor portion 40 of the multilayer ceramic electronic component 100 is disposed in the opposite direction from the mounting substrate 70. That is, the conductor portion 40 of the multilayer ceramic electronic component 100 is preferably disposed on a side closer to the first main surface (non-mounting surface) of the multilayer ceramic capacitor 10, and the multilayer ceramic capacitor 10 of the multilayer ceramic electronic component 100 is preferably disposed on a side closer to the mounting substrate 70. In the mounting as described above, since the distance between the multilayer ceramic capacitor 10 and the mounting substrate 70 is not increased, the effect of low ESL can be easily obtained. In addition, they can be mounted without affecting the mounting of the multilayer ceramic electronic component 100 on the mounting substrate.

In addition, as illustrated in FIGS. 14 and 15, in a mounting structure 500A of the multilayer ceramic electronic component, the conductor portion 40 of the multilayer ceramic electronic component 100 may be disposed on a surface orthogonal to the mounting substrate 70. That is, the conductor portion 40 may be disposed on the first side surface 12c or the second side surface 12d of the multilayer ceramic capacitor 10 with respect to the multilayer ceramic electronic component 100. In the mounting as described above, the mounting structure 500A of the multilayer ceramic electronic component achieves effects similar to those of the mounting structure 500 of the multilayer ceramic electronic component and additionally achieves the following effects.

That is, the length of the conductor portion 40 of the multilayer ceramic electronic component 100 can be determined according to dimension T, which is the length in the lamination direction x of the multilayer ceramic capacitor 10, and low profile can be achieved.

### 3. Method of Manufacturing Multilayer Ceramic Electronic Component

A non-limiting example of a method of manufacturing the multilayer ceramic capacitor 10 of the multilayer ceramic electronic component 100 according to the present example embodiment of the present invention will be described below.

### (a) Method of Manufacturing Multilayer Ceramic Capacitor

First, a dielectric sheet for the dielectric layers and a conductive paste for the inner electrode layers are prepared. The dielectric sheet and the conductive paste for the inner electrode layers contain a binder and a solvent. The binder and the solvent may be known ones.

Next, the conductive paste for the inner electrode layer is printed in a predetermined pattern on the dielectric sheet, for example, by screen printing or gravure printing. As a result, a dielectric sheet including patterns of the first inner electrode layer 16a and the second inner electrode layer 16b is prepared. More specifically, for example, a screen plate for printing the first inner electrode layer 16a and a screen plate for printing the second inner electrode layer 16b are prepared separately, the inner electrode layers 16 according to the present example embodiment can be printed separately by using a printing machine capable of separately printing the two types of screen plates. Here, the portion that becomes the inner layer portion 15a is formed by laminating a sheet on which the first inner electrode layer 16a is printed and a sheet on which the second inner electrode layer 16b is printed together so as to obtain a desired structure. In the present example embodiment, the inner electrode layers 16 are printed by using screen printing.

Next, by laminating a predetermined number of dielectric sheets on which the pattern of the inner electrode layer is not printed, the portion that becomes the first outer layer portion 15b1 closer to the first main surface 12a is formed. After that, the prepared portion that becomes the inner layer portion 15a is laminated, a predetermined number of dielectric sheets on which the pattern of the inner electrode layer is not printed are laminated on the portion that becomes the inner layer portion 15a, and accordingly, the portion that becomes the second outer layer portion 15b2 closer to the second main surface 12b is formed. As a result, the laminated sheets are manufactured.

Next, a laminated block is manufactured by pressing the laminated sheets in the lamination direction by using a method such as hydrostatic pressing.

Next, the laminated block is cut to a predetermined size, and accordingly, laminated chips are extracted. At this time, the corner portions and the ridge portions of the laminated chip may be rounded by barrel polishing or the like.

Next, the multilayer body 12 is manufactured by burning the laminated chip. The burning temperature is preferably, for example, about 900° C. or more and about 1400° C. or less, which depends on the materials of the dielectric layer 14 and the inner electrode layer 16.

The third underlying electrode layer 32c of the third outer electrode 30c and the fourth underlying electrode layer 32d of the fourth outer electrode 30d are formed on the first side surface 12c and the second side surface 12d of the multilayer body 12 obtained by burning.

When the baking layer is formed as the underlying electrode layer 32, a conductive paste including glass components and metal components is applied, and a baking treatment is performed to form the underlying electrode layer 32. The temperature for the baking treatment at this time is preferably, for example, about 700° C. or more and about 900° C. or less. In the present example embodiment, the underlying electrode layer 32 is formed as the baking layer.

Here, various methods can be used to form the baking layers as the third underlying electrode layer 32c and the fourth underlying electrode layer 32d. For example, it is possible to use a method that extrudes conductive paste through a slit and applies the conductive paste to form the third underlying electrode layer 32c and the fourth underlying electrode layer 32d. In this method, by increasing the amount of conductive paste extruded, the third underlying electrode layer 32c and the fourth underlying electrode layer 32d can be formed so as to extend not only onto the first side surface 12c and the second side surface 12d but also onto a portion of the first main surface 12a and a portion of the second main surface 12b.

The roller transfer method can also be used to form the underlying electrode layers. In the case of the roller transfer method, when the third underlying electrode layer 32c and the fourth underlying electrode layer 32d are formed not only on the first side surface 12c and the second side surface 12d but also on a portion of the first main surface 12a and a portion of the second main surface 12b, the third underlying electrode layer 32c and the fourth underlying electrode layer 32d can be formed on a portion of the first main surface 12a and a portion of the second main surface 12b by increasing the pressing pressure during the roller transfer.

Next, the first underlying electrode layer 32a of the first outer electrode 30a and the second underlying electrode layer 32b of the second outer electrode 30b are formed on the first end surface 12e and the second end surface 12f of the multilayer body 12 obtained by burning. When the baking layers are formed as the first underlying electrode layer 32a and the second underlying electrode layer 32b as in the third underlying electrode layer 32c and the fourth underlying electrode layer 32d, a conductive paste including glass components and metal components is applied, a baking treatment is performed, and the first underlying electrode layer 32a and the second underlying electrode layer 32b are formed. The temperature of the baking treatment at this time is preferably, for example, about 700° C. or more and about 900° C. or less.

It should be noted that, in the baking treatment, the first underlying electrode layer 32a of the first outer electrode 30a, the second underlying electrode layer 32b of the second outer electrode 30b, the third underlying electrode layer 32c of the third outer electrode 30c, and the fourth underlying electrode layer 32d of the fourth outer electrode 30d may be baked at the same time, or the third underlying electrode layer 32c of the third outer electrode 30c and the fourth underlying electrode layer 32d of the fourth outer electrode 30d on the side surface side and the first underlying electrode layer 32a of the first outer electrode 30a and the second underlying electrode layer 32b of the second outer electrode 30b on the end surface side may be baked separately from each other.

When the underlying electrode layer 32 is formed of a conductive resin layer, the conductive resin layer can be formed by using the following method. It should be noted that the conductive resin layer may be formed on the surface of the baking layer or may be formed directly on the multilayer body 12 without the baking layer being formed.

In the method of forming a conductive resin layer, a conductive resin paste including a thermosetting resin and metal components is applied onto a baking layer or a multilayer body 12, a heat treatment at a temperature of, for example, about 250° C. or higher and about 550° C. or lower is performed, and the resin is hardened to form the conductive resin layer. The atmosphere during the heat treatment at this time is preferably an N2 atmosphere.

In addition, the oxygen concentration is preferably suppressed to about 100 ppm or lower, for example, to prevent the scattering of resin and the oxidation of various metal components.

In the method of applying a conductive resin paste, as in the method that forms the underlying electrode layer 32 as the baking layer, for example, a method that extrudes a conductive resin paste through a slit and applies the resin paste or a roller transfer method can be used.

When the underlying electrode layer 32 is formed as a thin film layer, masking and other treatments can be performed to create the underlying electrode layer 32 in a portion in which the underlying electrode layer 32 needs to be formed by using a thin film formation method, such as a sputtering or deposition method. The underlying electrode layer 32 formed as a thin film layer is a layer with a thickness of about 1 μm or less, for example, on which metal particles have been deposited.

Finally, the plating layer 34 is formed. It should be noted that the plating layer 34 may be formed on the surface of the underlying electrode layer 32 or may be formed directly on the multilayer body 12. In the present example embodiment, the plating layer 34 is provided on the surface of the underlying electrode layer 32. More specifically, a Ni plating layer and a Sn plating layer are formed on the underlying electrode layer 32. The plating treatment may be either electrolytic plating or electroless plating. However, electroless plating requires a pretreatment using catalysts or the like to improve the plating deposition rate and has disadvantages such as complicated processes. Accordingly, electrolytic plating is preferably used normally.

As described above, the multilayer ceramic capacitor 10 as described in FIG. 1 can be manufactured.

### (b) Method of Manufacturing Conductor Portion

Next, the method of manufacturing the conductor portion 40 of the multilayer ceramic electronic component 100 according to the present example embodiment of the present invention will be described.

The conductor portions 40 can be manufactured by first manufacturing an aggregation of the conductor portions 40 and separating the aggregation of conductor portions 40.

The aggregation of the conductor portion 40 is manufactured by using the same method as typical printed circuit boards.

The conductor portion 40 that is a single-sided substrate is manufactured as described below.

That is, a material in which copper foil is disposed on one main surface of the insulating base material is prepared, and this material is cut to a predetermined dimension. Next, etching resist is printed on a portion (for example, a conductive pattern) in which the copper foil remains. Next, the copper foil other than the portion in which etching resist has been applied is removed by etching. After that, the remaining portion of the etching resist is removed, and a conductive pattern is formed. Next, a solder resist is printed to achieve insulation between conductive patterns and prevent solder from adhering to unnecessary portions during a soldering process, and the solder resist is UV cured to form a protective layer. Finally, surface treatments, such as solder plating, electroless gold plating, and a water-soluble flux treatment, are performed on the exposed electrode portion in which the conductive pattern is exposed, to improve solderability and prevent rusting of the copper foil.

As a result, an aggregation of the conductor portions 40, which is a single-sided substrate, is manufactured.

The conductor portion 40B, which is an example of a double-sided substrate, is manufactured as described below.

That is, a material in which copper foil is disposed on both main surfaces of the insulating substrate is prepared, and then the material is cut to a predetermined dimension. Next, boring to create through-holes and via holes is performed at predetermined positions of the cut material. Next, interlayer connection conductors (penetrating through-holes) are formed by through-hole plating to electrically connect the copper foil surfaces disposed on both main surfaces of the insulating base material. Next, dry films (etching resists) are laminated onto both main surfaces of the insulating substrate. Next, exposure and development are performed, and the dry film is printed only on the inner layer pattern. Next, the dry film of the unnecessary portion other than the conductive pattern is removed, and the resist for forming the conductive pattern is completed. Next, the copper foil in the portion other than the conductive pattern is removed by etching. Next, the remaining portion of the etching resist is removed, and a conductive pattern is formed. Next, a solder resist is formed to achieve insulation between conductive patterns and prevent solder from adhering to unnecessary portions during a soldering process to form a protective layer. Finally, surface treatments, such as solder plating, electroless gold plating, and a water-soluble flux treatment, are performed on a portion in which a conductive pattern is exposed, to improve solderability and prevent rusting of the copper foil.

As a result, an aggregation of the conductor portions 40B, which is an example of a double-sided substrate, is manufactured.

The conductor portion 40D, which is an example of the multilayer substrate, is manufactured as described above.

That is, first, the inner layer substrate and the outer layer substrate in which copper foil disposed on the surface of the insulating base material are cut to a predetermined dimension. Next, dry films (etching resists) are laminated onto both main surfaces of the cut material. Next, exposure and development are performed, and the dry films is printed only on the inner layer pattern. Next, the unnecessary portions other than the conductive pattern are removed, and the resist for forming the conductive pattern is completed. Next, the copper foil in the portion other than the conductive pattern is removed by etching. Next, the remaining portion of the etching resist is removed, and the conductive pattern is formed. Next, the multilayer substrate is manufactured by pressing and bonding the inner layer substrate and the outer layer substrate on which the conductive patterns have been formed by using a prepreg (insulating base material). Next, boring to create through-holes and via holes is performed at predetermined positions of the multilayer substrate. Next, interlayer connection conductors (penetrating through-holes) are formed by through-hole plating to electrically connect the copper foil surfaces disposed on both main surfaces of the multilayer substrate to each other. Next, dry films (etching resists) are laminated onto both main surfaces of the multilayer substrate. Next, exposure and development are performed, and the dry film is printed only on the outer layer pattern. Next, the unnecessary portions other than the conductive pattern are removed, and the resist for forming the conductive pattern is completed. Next, the copper foil in the portion other than the conductive pattern is removed by etching. Next, the remaining portion of the etching resist is removed, and a conductive pattern is formed. Next, after conductive pattern is formed, a solder resist is formed to achieve insulation between conductive patterns and prevent solder from adhering to unnecessary portions during a soldering process to form a protective layer. Finally, surface treatments, such as solder plating, electroless gold plating, and a water-soluble flux treatment, are performed on a portion in which a conductive pattern is exposed, to improve solderability and prevent rusting of the copper foil.

As a result, an aggregation of the conductor portions 40D, which is an example of a multilayer substrate, is manufactured.

### (c) Method of Manufacturing Multilayer Ceramic Electronic Component

Next the aggregation of the conductor portions 40 manufactured by the method described above is separated, and the multilayer ceramic capacitors 10 manufactured by the method described above are mounted. It should be noted that the conductor portion 40A to the conductor portion 40D are also the same.

More specifically, a cutting support tape is affixed to the aggregation of the conductor portions 40. Next, the aggregation of the conductor portion 40 is cut to a predetermined size for separation. Next, the separated conductor portions 40 are transferred onto the heat-resistant plate. It should be noted that, during the transfer, a heat-resistant tape or an adhesive may be disposed on the heat-resistant plate. Next, the conductive adhesive conductor portion 42 (solder) is printed onto the separated conductor portions 40, and the multilayer ceramic capacitors 10 are mounted by a mounter. Next, soldering is performed in a reflow oven. Finally, the separated conductor portions 40 are removed from the heat-resistant plate and washed with a flux.

As described above, the multilayer ceramic electronic component 100 illustrated in FIG. 1 is manufactured.

### 4. Modifications of Multilayer Ceramic Capacitor According to Present Example Embodiment

Modifications (first to third modifications) of the multilayer ceramic capacitor of the multilayer ceramic electronic component according to the present example embodiment will be described below. In addition, components of these modifications that correspond to those in the present example embodiment described above are denoted by the same reference numerals, and detailed descriptions thereof are omitted.

### (1) First Modification

A multilayer ceramic capacitor 10A according to the first modification of the present example embodiment differs from the multilayer ceramic capacitor 10 according to the above-described example embodiment only in the structure of the multilayer body 12A of the multilayer ceramic capacitor 10A. Accordingly, the same portions as the multilayer ceramic capacitor 10 are denoted by the same reference numerals, and the descriptions thereof are omitted.

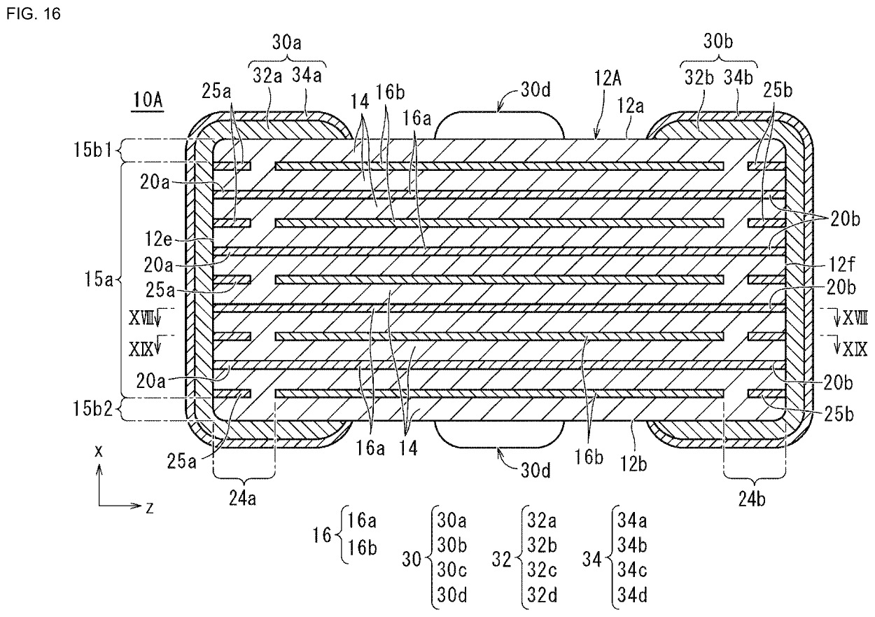

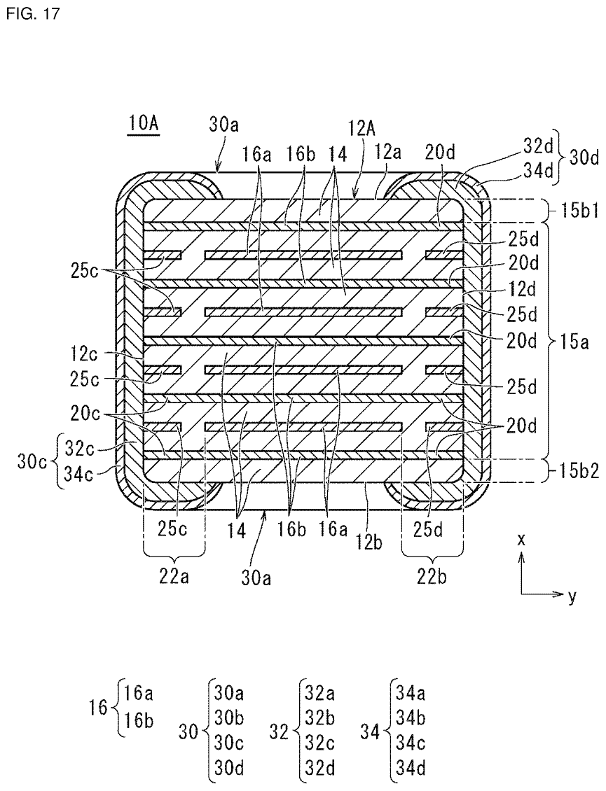

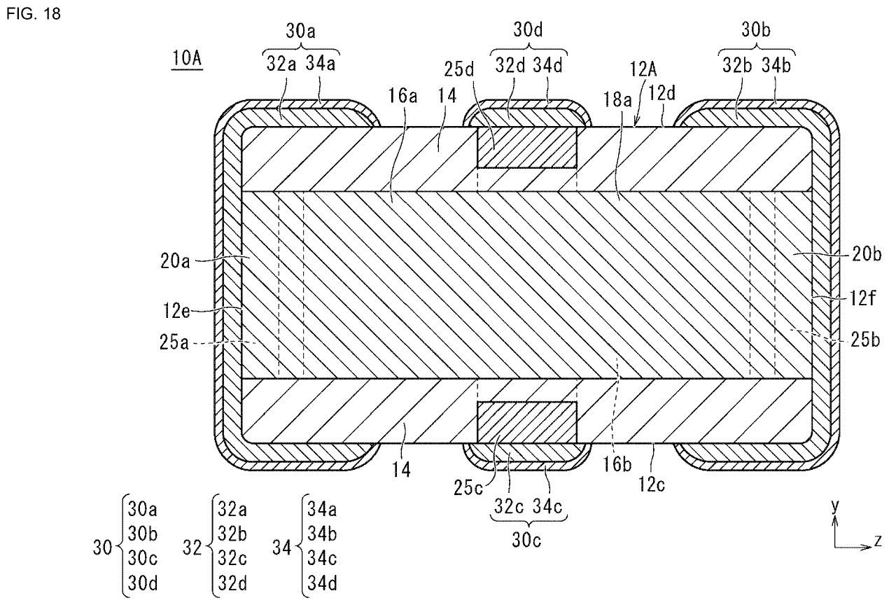

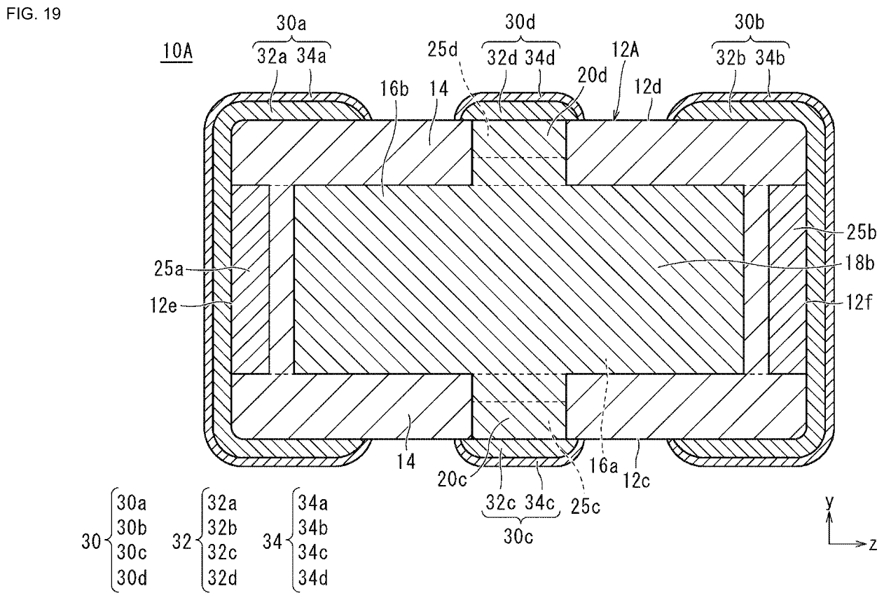

FIG. 16 is a cross-sectional view illustrating the first modification of the multilayer ceramic capacitor according to the present example embodiment of the present invention and corresponds to the cross-sectional view in FIG. 6. FIG. 17 is a cross-sectional view illustrating the first modification of the multilayer ceramic capacitor according to the present example embodiment of the present invention and corresponds to the cross-sectional view in FIG. 7. FIG. 18 is a cross-sectional view taken along line XVIII-XVIII in FIG. 16. FIG. 19 is a cross-sectional view taken along line XIX-XIX in FIG. 16.

The multilayer ceramic capacitor 10A includes the multilayer body 12A and the outer electrode 30.

The multilayer body 12A includes the plurality of dielectric layers 14 having been laminated together. In addition, the multilayer body 12A includes the first main surface 12a and the second main surface 12b that face away from each other in the lamination direction x, the first side surface 12c and the second side surface 12d that face away from each other in the width direction y orthogonal to the lamination direction x, and the first end surface 12e and the second end surface 12f that face away from each other in the length direction z orthogonal to both the lamination direction x and the width direction y.

At the end portions (L-gaps) 24a and 24b of the multilayer body 12A, a first dummy electrode 25a is disposed to be exposed to the first end surface 12e, and a second dummy electrode 25b is disposed to be exposed to the second end surface 12f.

The first dummy electrode 25a and the second dummy electrode 25b are preferably disposed on the same plane as the second inner electrode layer 16b and have a thickness similar to that of the second inner electrode layer 16b.

The current path can be shortened by reduction in the coverage of the first dummy electrode 25a and the second dummy electrode 25b.

The first dummy electrode 25a and the second dummy electrode 25b may be disposed in the first outer layer portion 15b1 and the second outer layer portion 15b2. In this case, the first dummy electrode 25a and the second dummy electrode 25b may be disposed on portions corresponding to places reached by the end portions (L-gap) 24a and 24b of the multilayer body 212 being moved in parallel in the lamination direction x. In the disposition described above, the plating layer 34 can be easily formed when the plating layer 34 is provided without the underlying electrode layer 32 being provided.

It should be noted that, when the first dummy electrode 25a and the second dummy electrode 25b are provided on the same plane as the second inner electrode layer 16b, the first dummy electrode 25a and the second dummy electrode 25b can be disposed on the same plane as the second inner electrode layer 16b by the first dummy electrode 25a and the second dummy electrode 25b being printed together with the second inner electrode layer 16b when the second inner electrode layer 16b is printed.

In addition, in the side portions (W-gaps) 22a and 22b of the multilayer body 12A, a third dummy electrode 25c may be disposed to be exposed to the first side surface 12c, and a fourth dummy electrode 25d may be disposed to be exposed to the second side surface 12d.

Preferably, the third dummy electrode 25c and the fourth dummy electrode 25d are disposed on the same plane as the first inner electrode layer 16a and have a thickness equivalent to that of the first inner electrode layer 16a.

The current path can be shortened by reduction in the coverage of the third dummy electrode 25c and the fourth dummy electrode 25d.

The third dummy electrode 25c and the fourth dummy electrode 25d may be disposed in the first outer layer portion 15b1 and the second outer layer portion 15b2. In this case, the third dummy electrode 25c and the fourth dummy electrode 25c may be disposed on portions corresponding to places reached by the side portions (W-gap) 22a and 22b of a multilayer body 12A being moved in parallel in the lamination direction x. In the disposition described above, the plating layer 34 can be easily formed when the plating layer 34 is provided without the underlying electrode layer 32 being provided.

It should be noted that, when the third dummy electrode 25c and the fourth dummy electrode 25d are provided on the same plane as the first inner electrode layer 16a, the third dummy electrode 25c and the fourth dummy electrode 25d can be disposed on the same plane as the first inner electrode layer 16a by the third dummy electrode 25c and the fourth dummy electrode 25d being printed together with the second inner electrode layer 16b when the first inner electrode layer 16a is printed.

In the multilayer ceramic capacitor 10A illustrated in FIGS. 16 to 19, the first dummy electrode 25a, the second dummy electrode 25b, the third dummy electrode 25c, and the fourth dummy electrode 25d are disposed in the side portions (W-gaps) 22a and 22b of the multilayer body 12A and the end portions (L-gaps) 24a and 24b of the multilayer body 12A, and accordingly, distortion during pressing can be prevented.

### (2) Second Modification

A multilayer ceramic capacitor 10B according to the second modification of the present example embodiment differs from the multilayer ceramic capacitor 10 according to the above-described example embodiment only in the structure of the multilayer body 12B of the multilayer ceramic capacitor 10B. Accordingly, the same portions as the multilayer ceramic capacitor 10 are denoted by the same reference numerals, and the descriptions thereof are omitted.

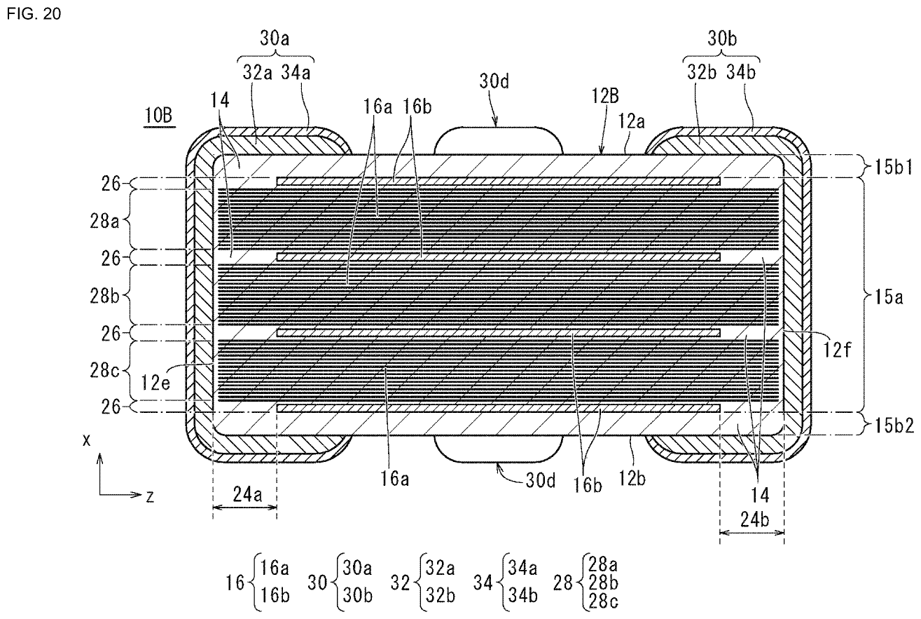

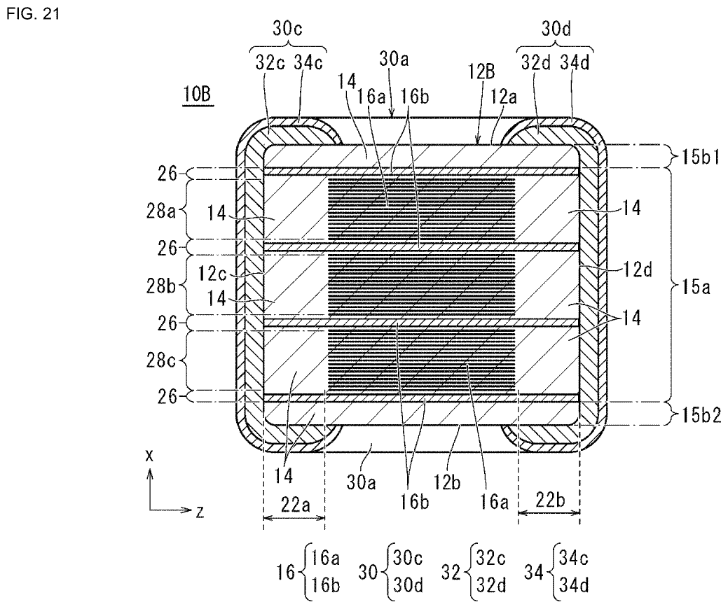

FIG. 20 is a cross-sectional view illustrating the second modification of the multilayer ceramic capacitor according to the present example embodiment of the present invention and corresponds to the cross-sectional view in FIG. 6. FIG. 21 is a cross-sectional view illustrating the second modification of the multilayer ceramic capacitor according to the present example embodiment of the present invention and corresponds to the cross-sectional view in FIG. 7.

The multilayer body 12B includes the plurality of dielectric layers 14 laminated together. In addition, the multilayer body 12B includes the first main surface 12a and the second main surface 12b that face away from each other in the lamination direction x, the first side surface 12c and the second side surface 12d that face away from each other in the width direction y orthogonal to the lamination direction x, and the first end surface 12e and the second end surface 12f that face away from each other in the length direction z orthogonal to both the lamination direction x and the width direction y.

The multilayer body 12B includes the inner layer portion 15a, and the first outer layer portion 15b1 and the second outer layer portion 15b2 that are disposed to sandwich the inner layer portion 15a in the lamination direction x.

The dielectric layer 14 of the inner layer portion 15a may be disposed so as to be sandwiched between the first inner electrode layer 16a and the first inner electrode layer 16a. In this case, the first inner electrode layer 16a and the first inner electrode layer 16a are continuously disposed via the dielectric layer 14 of the inner layer portion 15a.

Alternatively, the dielectric layer 14 of the inner layer portion 15a may also be disposed so as to be sandwiched between the second inner electrode layer 16b and the second inner electrode layer 16b. In this case, the second inner electrode layer 16b and the second inner electrode layer 16b are continuously disposed via the dielectric layer 14 of the inner layer portion 15a. The dielectric layer 14 of the inner layer portion 15a is formed of dielectric ceramic particles that have a perovskite structure and include, as a main component, perovskite compounds including, for example, Ba or Ti. In addition, at least one of Si, Mg, Ba, and Mn may be added to the main component as an additive. The additive is present between ceramic particles.

The inner layer portion 15a of the multilayer body 12B includes a capacitance forming portion 26 in which the first inner electrode layer 16a and the second inner electrode layer 16b face each other via the dielectric layer 14 to generate electrostatic capacitance, and an inner electrode laminated portion 28 in which two or more first inner electrode layers 16a are continuously laminated together. The multilayer ceramic capacitor 10B exhibits characteristics of the capacitor due to the capacitance forming portion 26.

In addition, the inner electrode laminated portion 28 is disposed to be divided into a plurality of inner electrode laminated portions 28 by the second inner electrode layers 16b. As a result, since the aggregation of the first inner electrode layers 16a is dispersed, the heat dissipation effects are enhanced, and effects of temperature rise suppression are obtained.

As illustrated in FIGS. 20 and 21, in the multilayer ceramic capacitors 10B, the inner electrode laminated portion 28 is divided by the two second inner electrode layers 16b, and the inner electrode laminated portion 28 is divided into a first inner electrode laminated portion 28a, a second inner electrode laminated portion 28b, and a third inner electrode laminated portion 28c.

It should be noted that the second inner electrode layer 16b disposed to divide the inner electrode laminated portion 28 in which two or more of first inner electrode layers 16a are continuously laminated may be a single layer. As a result, more first inner electrode layers 16a can be laminated, and the effects of reduction in DC resistance can be obtained.

In addition, the second inner electrode layer 16b is disposed to divide the inner electrode laminated portion 28 in which two or more of the first inner electrode layers 16a are continuously laminated together, but two or more second inner electrode layers 16b may also be continuously laminated and disposed. As a result, even if the number of the second inner electrode layers 16b is reduced, the connectivity between the second inner electrode layer 16b and the outer electrode 30 can be made more sufficient.

The second inner electrode layer 16b may be disposed between the inner electrode laminated portion 28 in which two or more first inner electrode layers 16a located closer to the first main surface 12a of the multilayer body 12B are continuously laminated, that is, the first inner electrode laminated portion 28a and the first main surface 12a and between the inner electrode laminated portion 28 in which two or more first inner electrode layers 16a located closer to the second main surface 12b of the multilayer body 12B are continuously laminated, that is, the third inner electrode laminated portion 28c and the second main surface 12b. As a result, since the capacitance forming portion 26 can be formed even near the first outer layer portion 15b1 and the second outer layer portion 15b2, the electrostatic capacitance is partially obtained, the current path to the mounting substrate can be shortened, and the effect of low ESL can be obtained.

In addition, the second inner electrode layer 16b does not need to be disposed between the inner electrode laminated portion 28 in which two or more first inner electrode layers 16a located closer to the first main surface 12a of the multilayer body 12B are continuously laminated, that is, the first inner electrode laminated portion 28a and the first main surface 12a or between the inner electrode laminated portion 28 in which two or more first inner electrode layers 16a located closer to the second main surface 12b of the multilayer body 12B are continuously laminated, that is, the third inner electrode laminated portion 28c and the second main surface 12b. As a result, since the distance from the surface of the multilayer body 12B to the capacitance forming portion 26 in which the electrostatic capacitance is formed is increased, even if cracks occur on the surface of the multilayer body 12B due to external stress, the insulation resistance is less likely to degrade.

The thickness of the dielectric layer 14 adjacent to the second inner electrode layer 16b is preferably greater than the thickness of the dielectric layer 14 sandwiched between the first inner electrode layers 16a. As a result, more first inner electrode layers 16a can be laminated together, the DC resistance can be further reduced.

In addition, the thickness of the second inner electrode layer 16b is preferably greater than the thickness of the first inner electrode layer 16a. As a result, even when the capacitance is lower, the connectivity between the third extended electrode portion 20c of the second inner electrode layer 16b and the third outer electrode 30c disposed on the first side surface 12c can be ensured, and the connectivity between the fourth extended electrode portion 20d of the second inner electrode layer 16b and the fourth outer electrode 30d disposed on the second side surface 12d can be ensured.

### (3) Third Modification

The multilayer ceramic capacitor 10C according to the third modification of the present example embodiment differs from the multilayer ceramic capacitor 10 according to the above-described example embodiment in that the multilayer body 12C of a multilayer ceramic capacitor 10C is covered with a coating layer 29. Accordingly, the same portions as the multilayer ceramic capacitor 10 are denoted by the same reference numerals, and the descriptions thereof are omitted.

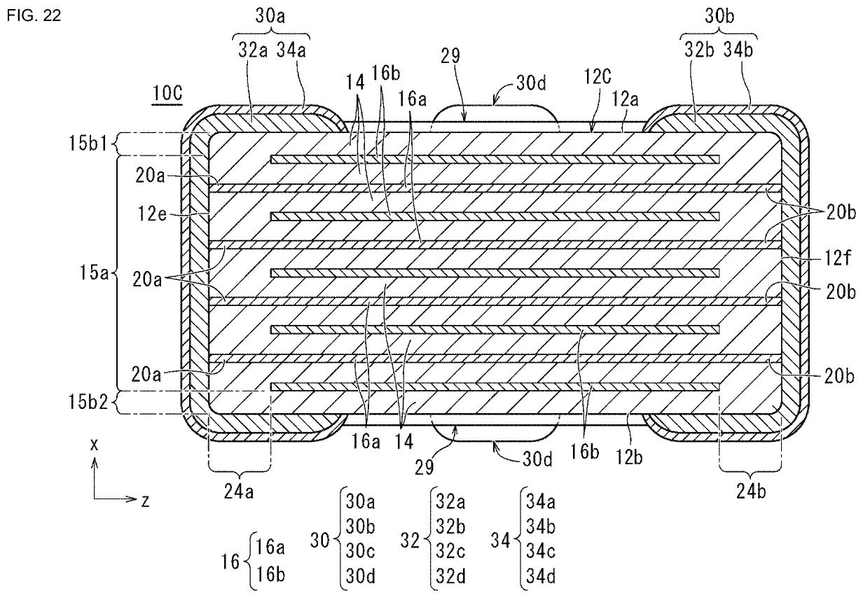

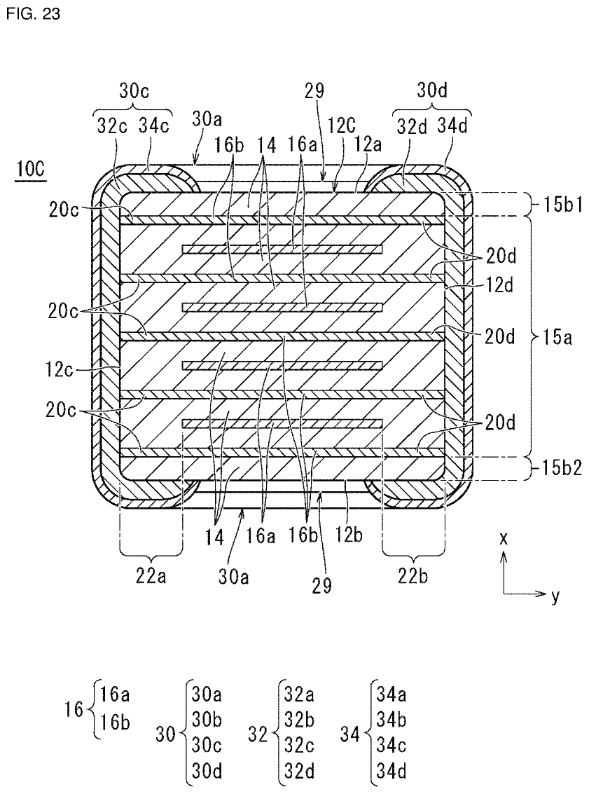

FIG. 22 is a cross-sectional view illustrating the third modification of the multilayer ceramic capacitor according to the present example embodiment of the present invention and corresponds to the cross-sectional view in FIG. 6. FIG. 23 is a cross-sectional view illustrating the third modification of the multilayer ceramic capacitor according to the present example embodiment of the present invention and corresponds to the cross-sectional view in FIG. 7.

A portion of the surface of the multilayer body 12C is provided with the coating layer 29 (silane coupling agent layer). In addition, the coating layer 29 is provided on at least one of the first main surface 12a and the second main surface 12b. More preferably, the coating layer 29 may be disposed on both the first main surface 12a and the second main surface 12b. In addition, the coating layer 29 may be disposed on the first side surface 12c and the second side surface 12d. In this case, the coating layer 29 is preferably disposed in a portion or all of the portion in which the first outer electrode 30a, the second outer electrode 30b, the third outer electrode 30c, or the fourth outer electrode 30d are not disposed on the first side surface 12c and the second side surface 12d.

The coating layer 29 provided on the surface of the multilayer body 12C can prevent moisture and flux from intruding into the multilayer body 12C from the outside. Accordingly, corrosion caused by organic acids included in the flux can be reduced or prevented during application of flux, and accordingly, the reliability of moisture resistance can be reduced or prevented from reducing.

The coating layer 29 is preferably made of a fluorine-based silane coupling agent or a carbon-based silane coupling agent.

The fluorine-based silane coupling agent included in the coating layer 29 is preferably a silane coupling agent represented by CF₃—(CF₂)ₙ₁—R—Si(O—R′)₃ (where n1 is a non-negative integer, R is a substituent group or an alkylene group including Si or O, and R′ is an alkyl group). For example, n1 may be an integer of 0 or more and 7 or less. In addition, R′ may be a methyl group or an ethyl group.

The silane coupling agent has at least one an alkoxy group, which is a reactive group. In addition, the silane coupling agent described above has one or more perfluoroalkyl groups.

The fluorine-based silane coupling agent may be, for example, one of the following agents.

CF₃(CF₂)₅(CH₂)₂Si(OCH₃)₃,

CF₃(CF₂)₃(CH₂)₂Si(OCH₃)₃,

CF₃(CF₂)₃(CH₂)₂Si(OC₂H₅)₃,

CF₃(CF₂)₇(CH₂)₂Si(OCH₃)₃,

CF₃CH₂O(CH₂)₁₅Si(OCH₃)₃,

CF₃(CH₂)₂Si(CH₃)₂(CH₂)₁₅Si(OCH₃)₃,

CF₃(CF₂)₃(CH₂)₂Si(CH₃)₂(CH₂)₉Si(OCH₃)₃,

CF₃COO(CH₂)₁₅Si(OCH₃)₃,

CF₃(CF₂)₅(CH₂)₂Si(OC₂H₅)₃,

CF₃(CF₂)₇(CH₂)₂Si(CH₃)₂(CH₂)₉Si(OC₂H₅)₃,

CF₃(CF₂)₇(CH₂)₂Si(CH₃)₂(CH₂)₆Si(OC₂H₅)₃,

CF₃(CF₂)₇(CH₂)₂Si(OC₂H₅)₃,

CF₃CH₂O(CH₂)₁₅Si(OC₂H₅)₃,

CF₃COO(CH₂)₁₅Si(OC₂H₅)₃,

CF₃(CF₂)₄CONH(CH₂)₃Si(OCH₃)₃,

CF₃(CF₂)₇CONH(CH₂)₃Si(OCH₃)₃,

CF₃(CF₂)₅CONH(CH₂)₃Si(OC₂H₅)₃, and

CF₃(CF₂)₇CONH(CH₂)₃Si(OC₂H₅)₃

The carbon-based silane coupling agent included in the coating layer 29 is preferably a silane coupling agent represented by (RO)₃Si—(CH₂)ₙ₂—CH₃ (where n2 is an integer of 0 or more and 17 or less, and R is a methyl group or an ethyl group).

The carbon-based silane coupling agent may be, for example, one of the following agents.

KBM-3103C (decyltrimethoxysilane),

KBM-13 (methyltrimethoxysilane),

KBE-13 (methyltriethoxysilane),

KBM-3033 (n-propyltrimethoxysilane),

KBE-3033 (n-propyltriethoxysilane),

KBM-3063 (hexyltrimethoxysilane),

KBE-3063 (hexyltriethoxysilane) manufactured by Shin-Etsu Chemical Co., Ltd., and octadecyltrimethoxysilane manufactured by Tokyo Chemical Industry (TCI).

Carbon-based silane coupling agents other than the above may be, for example, KBM-103 (phenylmethoxysilane), KBM-3066 (1,6-bis(trimethoxysilyl) hexane), and KBM-9659 (tris(trimethoxysilylpropyl) isocyanurate) manufactured by Shin-Etsu Chemical.

The coating layer 29 can be formed by manufacturing the multilayer ceramic capacitor 10C and immersing the multilayer ceramic capacitor 10C in the fluorine-based silane coupling agent or the carbon-based silane coupling agent.

Since the coating layer 29 covers all or a portion of the region in which the first outer electrode 30a, the second outer electrode 30b, the third outer electrode 30c, or the fourth outer electrode 30d of the multilayer body 12C are not disposed in the multilayer ceramic capacitor 10C illustrated in FIGS. 22 and 23, the moisture resistance of the multilayer ceramic capacitor 10C can be improved in addition to the effect achieved by the multilayer ceramic capacitor 10 according to the first example embodiment.

As described above, the example embodiments of the present invention are described above, but the present invention is not limited to the description.

That is, various changes can be made to elements, features, characteristics, shapes, materials, quantities, positions, or dispositions in the example embodiments described above, and these changes are included in the present invention.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer ceramic electronic component comprising:
a multilayer ceramic capacitor including:
a multilayer body that includes a plurality of dielectric layers, a first main surface and a second main surface that face away from each other in a lamination direction, a first side surface and a second side surface that face away from each other in a width direction orthogonal to the lamination direction, a first end surface and a second end surface that face away from each other in a length direction orthogonal to both the lamination direction and the width direction, a first inner electrode layer exposed to the first end surface and the second end surface, and a second inner electrode layer exposed to the first side surface and the second side surface;
a first outer electrode and a second outer electrode that are connected to the first inner electrode layer; and
a third outer electrode and a fourth outer electrode that are connected to the second inner electrode layer; and
a conductor portion electrically connected to the first outer electrode and the second outer electrode; wherein
a DC resistance RdcA of the conductor portion is smaller than a DC resistance RdcB of the multilayer ceramic capacitor.

2. The multilayer ceramic electronic component according to claim 1, wherein the first inner electrode layer and the second inner electrode layer are alternately positioned in the lamination direction via the dielectric layer.

3. The multilayer ceramic electronic component according to claim 1, wherein two or more first inner electrode layers are alternately positioned with the dielectric layer continuously in the lamination direction, the first inner electrode layer being one of the two or more first inner electrode layers.

4. The multilayer ceramic electronic component according to claim 1, wherein the conductor portion is not electrically joined to the third outer electrode or the fourth outer electrode.

5. The multilayer ceramic electronic component according to claim 1, wherein the conductor portion includes an interposer substrate.

6. The multilayer ceramic electronic component according to claim 1, wherein the conductor portion is on a surface of the multilayer body that is closer to the first main surface, the first side surface, or the second side surface.

7. The multilayer ceramic electronic component according to claim 1, further comprising a first dummy electrode exposed to the first end surface and a second dummy electrode exposed to the second end surface.

8. The multilayer ceramic electronic component according to claim 7, further comprising a third dummy electrode exposed to the first side surface and a fourth dummy electrode exposed to the second side surface.

9. The multilayer ceramic electronic component according to claim 1, wherein
the multilayer body includes an inner layer portion, a first outer layer portion and a second outer layer portion;
the inner layer portion is sandwiched between the first outer layer portion and the second outer layer portion;
the inner layer portion includes one of the plurality of dielectric layers sandwiched between two of the first inner electrode layers or two of the second inner electrode layers.

10. The multilayer ceramic electronic component according to claim 1, wherein the multilayer body includes a coating layer on at least one of the first main surface, the second main surface, the first side surface, or the second side surface.

11. A mounting structure of a multilayer ceramic electronic component, the mounting structure comprising:
the multilayer ceramic electronic component according to claim 1; and
a mounting substrate on which the multilayer ceramic electronic component is mounted; wherein
the multilayer ceramic electronic component is mounted such that the conductor portion does not face the mounting substrate.

12. The mounting structure according to claim 11, wherein the first inner electrode layer and the second inner electrode layer are alternately positioned in the lamination direction via the dielectric layer.

13. The mounting structure according to claim 11, wherein two or more first inner electrode layers are alternately positioned with the dielectric layer continuously in the lamination direction, the first inner electrode layer being one of the two or more first inner electrode layers.

14. The mounting structure according to claim 11, wherein the conductor portion is not electrically joined to the third outer electrode or the fourth outer electrode.

15. The mounting structure according to claim 11, wherein the conductor portion includes an interposer substrate.

16. The mounting structure according to claim 11, wherein the conductor portion is on a surface of the multilayer body that is closer to the first main surface, the first side surface, or the second side surface.

17. The mounting structure according to claim 11, further comprising a first dummy electrode exposed to the first end surface and a second dummy electrode exposed to the second end surface.

18. The mounting structure according to claim 17, further comprising a third dummy electrode exposed to the first side surface and a fourth dummy electrode exposed to the second side surface.

19. The mounting structure according to claim 11, wherein
the multilayer body includes an inner layer portion, a first outer layer portion and a second outer layer portion;
the inner layer portion is sandwiched between the first outer layer portion and the second outer layer portion;
the inner layer portion includes one of the plurality of dielectric layers sandwiched between two of the first inner electrode layers or two of the second inner electrode layers.

20. The mounting structure according to claim 11, wherein the multilayer body includes a coating layer on at least one of the first main surface, the second main surface, the first side surface, or the second side surface.
